(19) United States
(12) Patent Application Publication
(10) Pub. No.: US 2024/0334782 A1
(43) Pub. Date: Oct. 3, 2024

(54) DISPLAY DEVICE

(71) Applicant: Samsung Display Co., LTD., Yongin-si (KR)

(72) Inventors: June Hwan KIM, Yongin-si (KR); Chang Min SONG, Yongin-si (KR); Dong Gi AHN, Yongin-si (KR); Seok Won JEONG, Yongin-si (KR); Dae Youn CHO, Yongin-si (KR)

(73) Assignee: Samsung Display Co., LTD., Yongin-si (KR)

(21) Appl. No.: 18/509,311

(22) Filed: Nov. 15, 2023

(30) Foreign Application Priority Data
Mar. 27, 2023 (KR) 10-2023-0039560

(51) Int. Cl. H10K 59/80; H10K 59/122; H10K 59/131; H10K 59/35

(52) U.S. Cl. CPC H10K 59/871; H10K 59/122; H10K 59/1315; H10K 59/353; H10K 59/874; H10K 59/8793

(57) ABSTRACT

A display device includes a substrate, a circuit layer, a light emitting element layer, a sealing layer, and a polarization layer. A main area of the substrate includes a display area including emission areas and a non-display area disposed around the display area, the non-display area includes a dam area spaced apart from the display area, the dam area including at least one dam portion surrounding the display area. The non-display area also including a bonding area that surrounds the dam area, the circuit layer includes a buffer portion disposed in a part of the bonding area adjacent to the sub-area, the buffer portion being spaced apart from each of the sub-area and the dam area, and the polarization layer extends to the non-display area and overlaps the buffer portion.

### CROSS-REFERENCE TO RELATED APPLICATIONS

This application claims priority under 35 U.S.C. § 119 from Korean Patent Application No. 10-2023-0039560 filed on Mar. 27, 2023 in the Korean Intellectual Property Office, the entire contents of which are incorporated herein by reference.

### BACKGROUND

### 1. Technical Field

The disclosure relates to a display device.

### 2. Description of the Related Art

As the information society develops, demands for display devices for displaying images may be increasing in various forms. For example, display devices may be applied to various electronic devices such as smartphones, digital cameras, notebook computers, navigation devices, and smart televisions.

The display devices may be flat panel display devices such as liquid crystal display devices, field emission display devices, and light emitting display devices. Among these flat panel display devices, the light emitting display devices may include an organic light emitting display device including an organic light emitting element, an inorganic light emitting display device including an inorganic light emitting element such as an inorganic semiconductor, and a micro- or nano-light emitting display device including a micro- or nano-light emitting element.

An organic light emitting display device displays an image using light emitting elements, each including a light emitting layer of an organic light emitting material. The organic light emitting display device that displays an image using the self-light emitting elements may have relatively superior performance in terms of power consumption, response speed, luminous efficiency, luminance, and wide viewing angle, compared with other display devices.

A surface of a display device may include a display area where an image may be displayed and a non-display area disposed around the display area. In the display area, emission areas emitting light with respective luminances and colors may be arranged.

The display device may include a substrate including the display area and the non-display area, a circuit layer including pixel drivers disposed on the substrate and respectively corresponding to the emission areas, a light emitting element layer including light emitting elements disposed on the circuit layer and respectively corresponding to the emission areas, and a sealing layer disposed on the light emitting element layer. The sealing layer may be bonded to an inorganic insulating material of the circuit layer in the non-display area to seal the light emitting element layer. The sealing layer may block permeation of oxygen or moisture, thereby preventing an organic light emitting material and the like of the light emitting element layer from deteriorating rapidly.

The circuit layer may include the pixel drivers, conductive layers for forming lines electrically connected to the pixel drivers, and insulating layers disposed between the conductive layers. Since the conductive layers of the circuit layer may be made of metal materials, at least one of the insulating layers of the circuit layer which may be adjacent to the substrate may include inorganic insulating materials. In addition, at least one of the insulating layers of the circuit layer which may be adjacent to the light emitting element layer may include relatively thick organic insulating materials in consideration of the uniformity of the direction in which the light emitting elements of the light emitting element layer emit light.

### SUMMARY

The display device may further include a polarization layer for reducing reflection of external light. The polarization layer may be attached onto the sealing layer through a laminating process using a roller.

However, during the laminating process, the pressure of the roller may increase in an area where the organic insulating materials have been removed from the circuit layer due to a step difference according to the presence or absence of the organic insulating materials. The conductive layers or the inorganic insulating materials may be damaged due to the high pressure of the roller, causing the lines of the circuit layer to be broken or to short-circuit. As a result, the quality, reliability and lifespan of the display device may be reduced.

Aspects of the disclosure provide a display device having improved quality, reliability and lifespan while including a polarization layer by reducing damage to a circuit layer due to a process of disposing the polarization layer.

However, aspects of the disclosure may not be restricted to the one set forth herein. The above and other aspects of the disclosure will become more apparent to one of ordinary skill in the art to which the disclosure pertains by referencing the detailed description of the disclosure given below.

According to an aspect of the disclosure, there may be provided a display device that may include a substrate including a main area and a sub-area protruding from a side of the main area; a circuit layer disposed on the substrate; a light emitting element layer disposed on the circuit layer; a sealing layer disposed on the light emitting element layer; and a polarization layer disposed on the sealing layer and overlapping the light emitting element layer. The main area may include a display area including emission areas and a non-display area disposed around the display area, the non-display area may include a dam area spaced apart from the display area, the dam area including at least one dam portion that surrounds the display area, and a bonding area surrounding the dam area, the circuit layer may include a buffer portion disposed in a part of the bonding area, the buffer portion may be spaced apart from each of the sub-area and the dam area, and the polarization layer may extend to the non-display area and overlaps the buffer portion.

The circuit layer may include a semiconductor layer disposed on the substrate, a first gate insulating layer disposed on the substrate and covering the semiconductor layer, a first conductive layer disposed on the first gate insulating layer, a second gate insulating layer disposed on the first gate insulating layer and covering the first conductive layer, a second conductive layer disposed on the second gate insulating layer, an interlayer insulating layer disposed on the second conductive layer and covering the second conductive layer, a third conductive layer disposed on the interlayer insulating layer, a first planarization layer disposed on the interlayer insulating layer and covering the third conductive layer, a fourth conductive layer disposed on the first planarization layer, and a second planarization layer disposed on the first planarization layer and covering the fourth conductive layer. The at least one dam portion and the buffer portion may be disposed on the interlayer insulating layer, and the sealing layer may contact the interlayer insulating layer in a portion of the bonding area external to the buffer portion.

A width of the buffer portion in a first direction may be equal to or greater than a width of the sub-area, the first direction may intersect a second direction, and the sub-area may protrude from the main area in the second direction.

The buffer portion may include a compensation pattern layer disposed on the interlayer insulating layer, a first compensation insulating layer covering the compensation pattern layer; and a second compensation insulating layer disposed on the first compensation insulating layer. The third conductive layer may include the compensation pattern layer, the first compensation insulating layer and the first planarization layer may be a same layer, and the second compensation insulating layer and the second planarization layer may be a same layer.

The compensation pattern layer may have a mesh shape, the compensation pattern layer may include grooves, and the grooves may be arranged side by side with each other, and the first compensation insulating layer may contact the interlayer insulating layer through each of the grooves.

Each of the grooves may have one of a circular shape and a polygonal shape.

The sealing layer may include a first sealing layer disposed in the main area and covering the light emitting element layer and the at least one dam portion, a second sealing layer disposed on the first sealing layer, overlapping the light emitting element layer, and including an organic insulating material, and a third sealing layer covering the second sealing layer. The second sealing layer may be disposed in a part of the main area, the main area being surrounded by the at least one dam portion, the first sealing layer may contact the interlayer insulating layer in a part of the bonding area external to the buffer portion, and the third sealing layer may contact the first sealing layer in the bonding area.

The first sealing layer may contact the interlayer insulating layer through at least one of the grooves in the compensation pattern layer.

The light emitting element layer may include light emitting elements respectively corresponding to the emission areas, the circuit layer may include a first power supply line and a second power supply line disposed in the non-display area and respectively transmitting a first power and a second power to drive the light emitting elements, and each of the first power supply line and the second power supply line may be spaced apart from the compensation pattern layer of the buffer portion.

The compensation pattern layer may be electrically connected to one of the first power supply line and the second power supply line.

The first power supply line may include a first power connection line extending from the non-display area to the sub-area, the second power supply line may include a second power connection line extending from the non-display area to the sub-area, each of the first power connection line, the second power connection line, and one of the third conductive layer and the fourth conductive layer are a same layer, the compensation pattern layer of the buffer portion may be divided into branches arranged side by side in the first direction, and the branches may be spaced apart from the first power connection line and the second power connection line in the first direction.

The display device may further include pixel drivers respectively corresponding to the emission areas and electrically connected to the light emitting elements of the light emitting element layer, respectively, data lines transmitting data signals to the pixel drivers, and data connection lines disposed in the non-display area, electrically connected to the data lines, respectively, and extending to the sub-area. The fourth conductive layer may include the data lines, the first conductive layer may include at least one of the data connection lines, the second conductive layer may include ones of the data connection lines not included in the first conductive layer, and at least a portion of each of the data connection lines may overlap the buffer portion.

The light emitting element layer may include anodes disposed on the second planarization layer of the circuit layer and respectively corresponding to the emission areas, a pixel defining layer disposed on the second planarization layer of the circuit layer, the pixel defining layer corresponding to a non-emission area between the emission areas, and the pixel defining layer covering edges of each of the anodes, light emitting layers disposed on the anodes, respectively, and a cathode disposed on the pixel defining layer and on the light emitting layers, the cathode facing the anodes. Each of the light emitting elements may include one of the light emitting layers disposed between one of the anodes and the cathode.

The sub-area may include a bending area transformed into a bent shape, a first sub-area disposed between a first side of the bending area and the main area, and a second sub-area extending to a second and opposite side of the bending area, and the circuit layer may further include data bending lines disposed in the bending area and electrically connected to the data connection lines, respectively, a bending aperture disposed in the bending area and penetrating the first gate insulating layer, the second gate insulating layer and the interlayer insulating layer, and a bank covering the bending aperture and spaced apart from the buffer portion. The bank may include a first bank layer covering the bending aperture, the first bank layer and the first planarization layer may be a same layer, and a second bank layer covering the first bank layer, the second bank layer and the second planarization layer may be a same layer, the fourth conductive layer may further include the data bending lines, the data bending lines may be disposed on the first bank layer, and the data bending lines may be covered by the second bank layer.

A portion of each of the first bank layer and the second bank layer may extend to the non-display area and overlaps the polarization layer.

The polarization layer may be spaced apart from the bank.

According to an aspect of the disclosure, there may be provided a display device that may include a substrate including a main area and a sub-area protruding from a side of the main area, a circuit layer disposed on the substrate, a light emitting element layer disposed on the circuit layer, a sealing layer disposed on the light emitting element layer, a touch sensor layer disposed on the sealing layer, and a polarization layer disposed on the touch sensor layer and overlapping the light emitting element layer. The main area may include a display area including emission areas, and a non-display area disposed around the display area, the non-display area may include a dam area spaced apart from the display area, the dam area including at least one dam portion surrounding the display area, and a bonding area surrounding the dam area, the circuit layer may include a buffer portion disposed in a part of the bonding area adjacent to the sub-area, the buffer portion being spaced apart from each of the sub-area and the dam area, the buffer portion may include a compensation pattern layer and at least one compensation insulating layer covering the compensation pattern layer, and the polarization layer may extend to the non-display area and may overlap the buffer portion.

A width of the compensation pattern layer in a first direction may be equal to or greater than a width of the sub-area, the first direction may intersect a second direction, and the sub-area may protrude from the main area in a first direction.

The light emitting element layer may include light emitting elements respectively corresponding to the emission areas, the circuit layer may include a first power supply line and a second power supply line disposed in the non-display area and respectively transmitting a first power and a second power to drive the light emitting elements, and the compensation pattern layer may be spaced apart from each of the first power supply line and the second power supply line.

The compensation pattern layer may be electrically connected to one of the first power supply line and the second power supply line.

The first power supply line may include a first power connection line extending from the non-display area to the sub-area, the second power supply line may include a second power connection line extending from the non-display area to the sub-area, each of the first power connection line and the second power connection line, and one of a first conductive layer and a second conductive layer may be a same layer, the compensation pattern layer of the buffer portion may be divided into branches arranged side by side in the first direction, and the branches may be spaced apart from the first power connection line and the second power connection line in the first direction.

The compensation pattern layer may have a mesh shape, the compensation pattern layer may include grooves, the grooves may be arranged side by side with each other, and each of the grooves may have one of a circular shape and a polygonal shape.

The circuit layer may include a semiconductor layer disposed on the substrate, a first gate insulating layer disposed on the substrate and covering the semiconductor layer, a first conductive layer disposed on the first gate insulating layer, a second gate insulating layer disposed on the first gate insulating layer and covering the first conductive layer, a second conductive layer disposed on the second gate insulating layer, an interlayer insulating layer disposed on the second conductive layer and covering the second conductive layer, a third conductive layer disposed on the interlayer insulating layer, a first planarization layer disposed on the interlayer insulating layer and covering the third conductive layer, a fourth conductive layer disposed on the first planarization layer, and a second planarization layer disposed on the first planarization layer and covering the fourth conductive layer. The at least one dam portion and the buffer portion may be disposed on the interlayer insulating layer, the sealing layer may contact the interlayer insulating layer in a portion of the bonding area external to the buffer portion, the compensation pattern layer of the buffer portion and the third conductive layer may be a same layer, and each of the at least one compensation insulating layer of the buffer portion may contact the interlayer insulating layer through each of the grooves, each of the at least one compensation insulating layer and one of the first planarization layer and the second planarization layer may be a same layer.

The sealing layer may include a first sealing layer disposed in the main area and covering the light emitting element layer and the at least one dam portion, a second sealing layer disposed on the first sealing layer, the second sealing layer may overlap the light emitting element layer, the second sealing layer may include an organic insulating material, and a third sealing layer may cover the second sealing layer. The second sealing layer may be disposed in a portion of the main area surrounded by the at least one dam portion, the first sealing layer may contact the interlayer insulating layer in the portion of the bonding area external to the buffer portion, and the third sealing layer may contact the first sealing layer in the bonding area.

The first sealing layer may contact the interlayer insulating layer through at least one of the grooves in the compensation pattern layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a plan view of the display device of FIG. 1;

FIG. 3 is a schematic cross-sectional view taken along line A-A′ of FIG. 2;

FIG. 4 is a plan view of a main area and a sub-area of the display device of FIG. 1 according to a first embodiment;

FIG. 5 is a plan view of portion B of FIG. 4;

FIG. 6 is a schematic diagram of an equivalent circuit of a pixel driver corresponding to one emission area among pixel drivers included in a circuit layer of FIG. 3;

FIG. 7 is a plan view of a touch sensor layer of FIG. 3;

FIG. 8 is an enlarged view of portion D of FIG. 7;

FIG. 9 is a schematic cross-sectional view taken along line E-E′ of FIG. 8;

FIG. 10 is a plan view of portion C of FIG. 4 according to the first embodiment;

FIG. 11 is a schematic cross-sectional view taken along line F-F′ of FIG. 10 according to the first embodiment;

FIG. 12 is a schematic cross-sectional view taken along line F-F′ of FIG. 10 according to a second embodiment;

FIG. 13 is a plan view of an example of a compensation pattern layer of a buffer portion according to a third embodiment;

FIG. 14 is a plan view of an example of a compensation pattern layer of a buffer portion according to a third embodiment;

FIG. 15 is a plan view of an example of a compensation pattern layer of a buffer portion according to a third embodiment;

FIG. 16 is a schematic cross-sectional view taken along line F-F″ of FIG. 10 according to the third embodiment;

FIG. 17 is a plan view of a compensation pattern layer of a buffer portion according to a fourth embodiment;

FIG. 18 is a schematic cross-sectional view taken along line F-F″ of FIG. 10 according to the fourth embodiment;

FIGS. 19 and 20 are plan views of portion C of FIG. 4 according to a fifth embodiment;

FIG. 21 is a schematic cross-sectional view taken along line G-G′ of FIG. 20; and

FIG. 22 is a plan view of portion C of FIG. 4 according to a sixth embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Further, the X-axis, the Y-axis, and the Z-axis may not be limited to three axes of a rectangular coordinate system, such as the x, y, and z axes, and may be interpreted in a broader sense. For example, the X-axis, the Y-axis, and the Z-axis may be perpendicular to one another, or may be different directions that may not be perpendicular to one another.

As used herein, the term “and/or” includes any and all combinations of one or more of the associated listed items. A description that a component is “configured to” perform a specified operation may be defined as a case where the component is constructed and arranged with structural features that can cause the component to perform the specified operation.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be disposed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, portion, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein. Hereinafter, embodiments will be described with reference to the accompanying drawings.

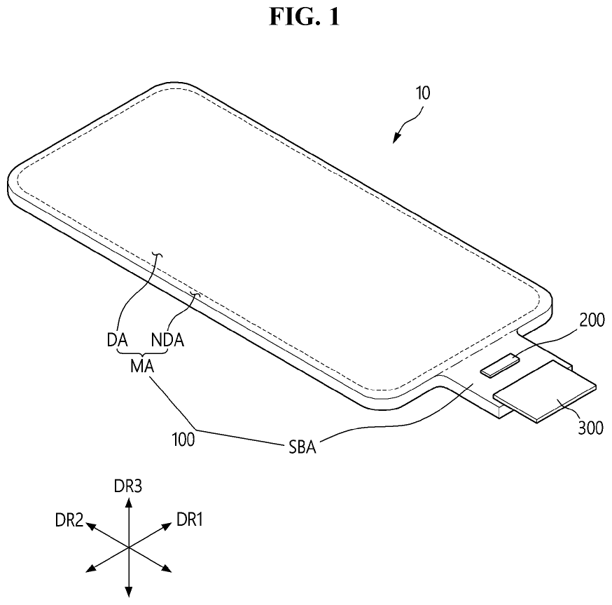

FIG. 1 is a perspective view of a display device 10 according to an embodiment.

Referring to FIG. 1, the display device 10 may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IoT) devices.

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode. A case where the display device 10 may be an organic light emitting display device will be described below. However, the disclosure may also be applicable to display devices including an organic insulating material, an organic light emitting material, and a metal material.

The display device 10 may be formed approximately flat, but the disclosure may not be limited thereto. For example, the display device 10 may include curved portions formed at left and right ends and having a constant or varying curvature. In addition, the display device 10 may be formed to be flexible so that it can be curved, bent, folded, or rolled.

The display device 10 may include a display panel 100, a display driving circuit 200, and a circuit board 300.

The display panel 100 may include a main area MA disposed on a surface where an image may be displayed and a sub-area SBA protruding from a side of the main area MA.

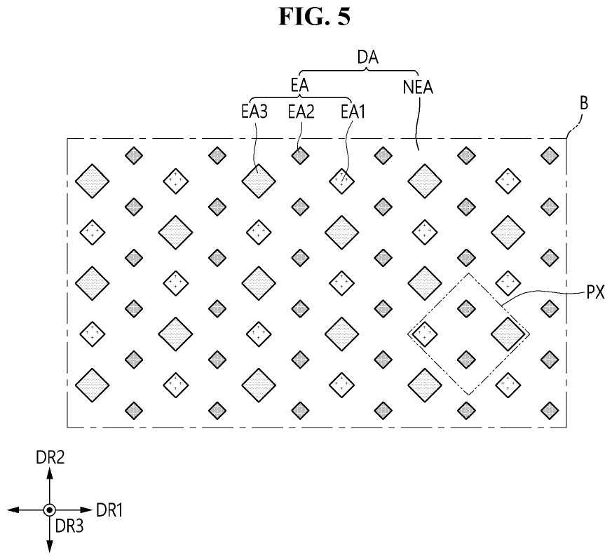

The main area MA may include a display area DA in which emission areas EA (see FIG. 5) emitting light with respective colors and luminances are arranged to display an image and a non-display area NDA disposed around the display area DA.

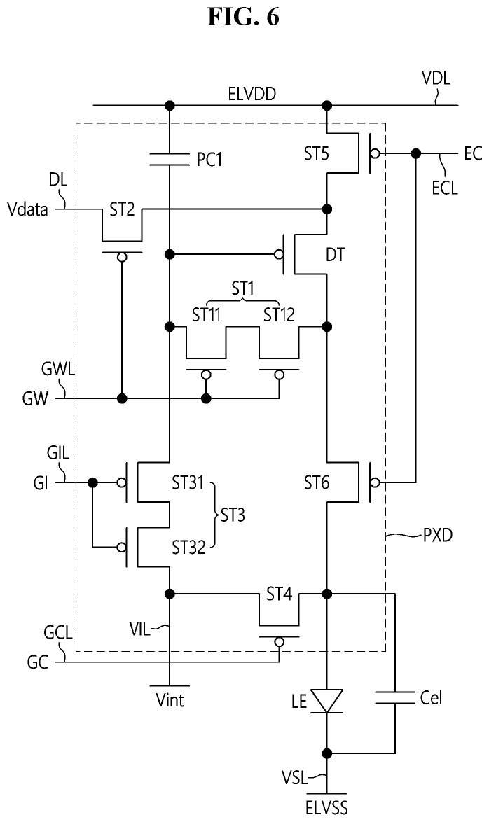

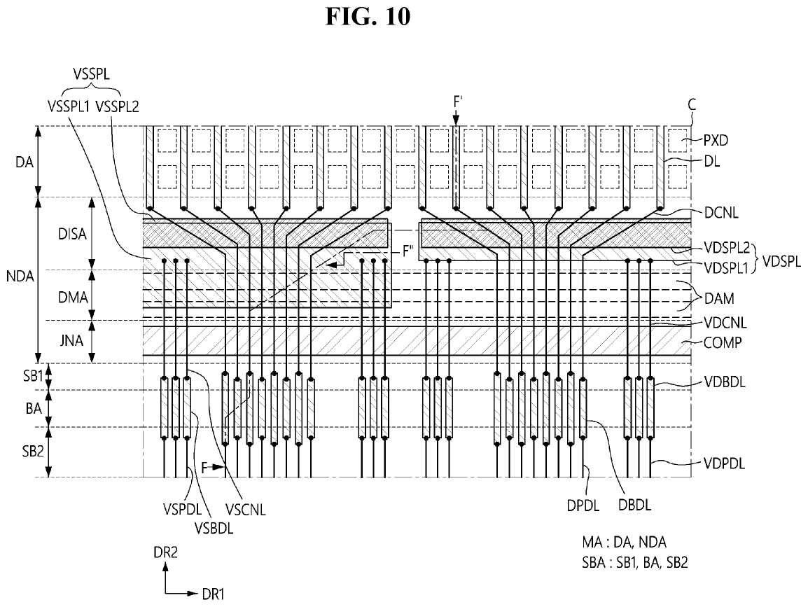

The display driving circuit 200 may be provided as an integrated circuit and mounted in the sub-area SBA. The display driving circuit 200 may supply data signals to data lines DL (see FIGS. 6 and 10) of the display panel 100.

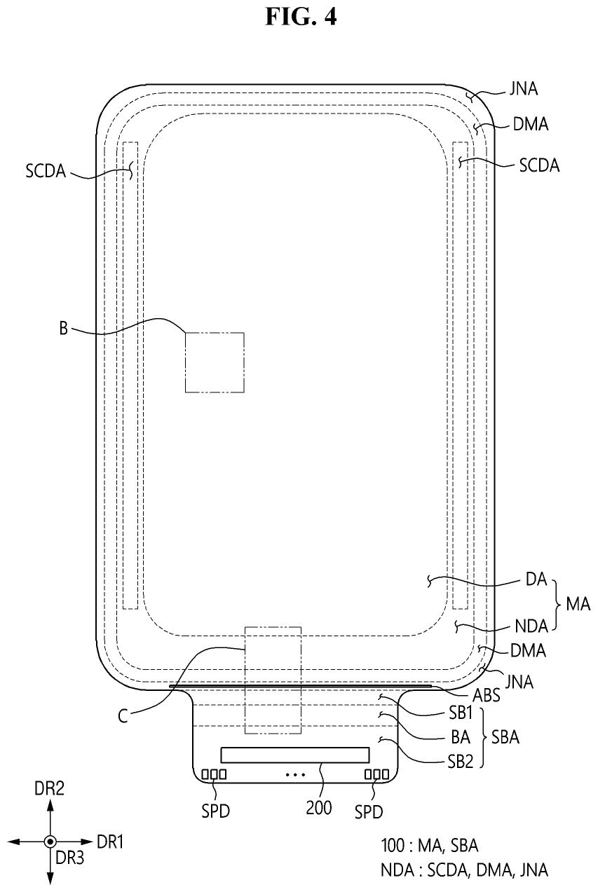

The circuit board 300 may be bonded to signal pads SPD (see FIG. 4) disposed on an edge of the sub-area SBA.

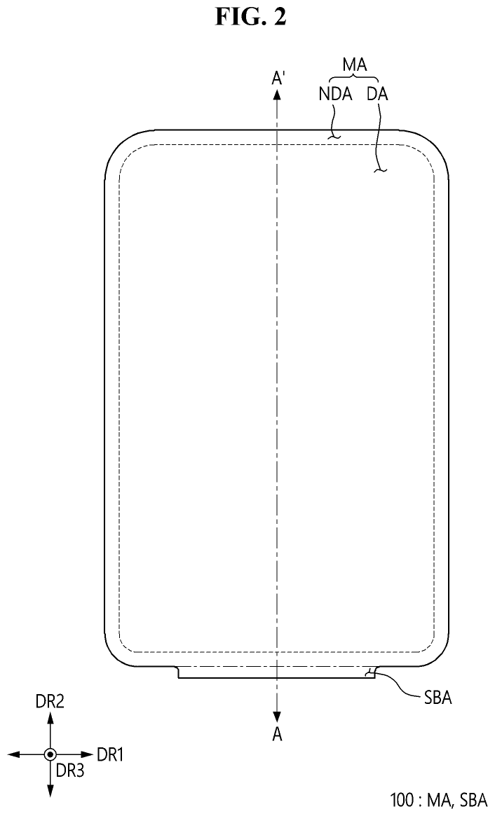

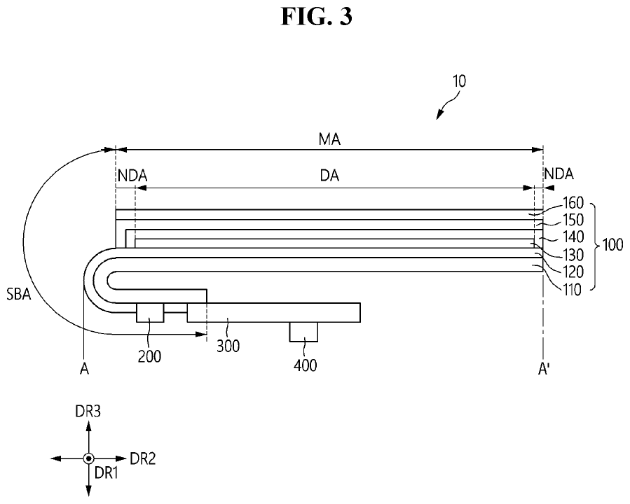

FIG. 2 is a plan view of the display device 10 of FIG. 1. FIG. 3 is a schematic cross-sectional view taken along line A-A′ of FIG. 2. FIG. 4 is a plan view of the main area MA and the sub-area SBA of the display device 10 of FIG. 1 according to a first embodiment.

In FIGS. 1 and 4, the sub-area SBA may be spread out parallel to the main area MA. On the other hand, in FIG. 2, a portion of the sub-area SBA may be bent.

Referring to FIG. 2, the display area DA may be shaped like a rectangular plane having short sides in a first direction DR1 and long sides in a second direction DR2 intersecting the first direction DR1. Each corner where a short side extending in the first direction DR1 meets a long side extending in the second direction DR2 may be rounded with a curvature or may be right-angled. The planar shape of the display area DA may not be limited to a quadrilateral shape but may also be another polygonal shape, a circular shape, or an oval shape.

The display area DA may occupy most of the main area MA. The display area DA may be disposed in a center of the main area MA.

Referring to FIG. 3, the display panel 100 of the display device 10 includes a substrate 110 including the main area MA and the sub-area SBA, a circuit layer 120 disposed on the substrate 110, a light emitting element layer 130 disposed on the circuit layer 120, and a sealing layer 140 disposed on the light emitting element layer 130.

The display panel 100 of the display device 10 according to the embodiment may further include a polarization layer 160 disposed on the sealing layer 140 and overlapping the light emitting element layer 130.

The display panel 100 of the display device 10 according to the embodiment may further include a touch sensor layer 150 disposed on the sealing layer 140. The polarization layer 160 may be disposed on the touch sensor layer 150.

The substrate 110 may be made of an insulating material such as polymer resin. For example, the substrate 110 may be made of polyimide. The substrate 110 may be a flexible substrate that can be bent, folded, or rolled.

The substrate 110 may instead be made of an insulating material such as glass.

The circuit layer 120 may include pixel drivers PXD (see FIG. 6) respectively corresponding to the emission areas EA. Each of the pixel drivers PXD may include two or more transistors DT and ST1 through ST6 (see FIG. 6) and at least one capacitor PC1 (see FIG. 6).

The light emitting element layer 130 may include light emitting elements LE (see FIG. 6) respectively corresponding to the emission areas EA. The light emitting elements LE of the light emitting element layer 130 may be electrically connected to the pixel drivers PXD of the circuit layer 120, respectively.

The sealing layer 140 may cover the light emitting element layer 130 and extend into the non-display area NDA to contact the circuit layer 120. The sealing layer 140 may include a structure in which two or more inorganic layers and at least one organic layer may be alternately stacked on each other.

The touch sensor layer 150 may be disposed on the sealing layer 140 and may correspond to the main area MA. The touch sensor layer 150 may include touch electrodes for sensing a touch of a person or object.

The polarization layer 160 blocks external light that may be reflected by the touch sensor layer 150, the sealing layer 140, the light emitting element layer 130, the circuit layer 120, and interfaces between them, thereby preventing a reduction in visibility of an image due to reflection of the external light.

The display device 10 may further include a cover window (not illustrated) disposed on the polarization layer 160. The cover window may be attached onto the polarization layer 160 by a transparent adhesive member such as an optically clear adhesive (OCA) film or an optically clear resin (OCR). The cover window may be an inorganic material such as glass or may be an organic material such as plastic or polymer material. The cover window may protect the touch sensor layer 150, the sealing layer 140, the light emitting element layer 130, and the circuit layer 120 from electrical and physical impact on a display surface.

The display device 10 according to the embodiment may further include a touch driving circuit 400 for driving the touch sensor layer 150.

The touch driving circuit 400 may be provided as an integrated circuit.

The touch driving circuit 400 may be mounted on the circuit board 300 bonded to the signal pads SPD and thus may be electrically connected to the touch sensor layer 150.

Like the display driving circuit 200, the touch driving circuit 400 may be mounted on a second sub-area SB2 of the substrate 110.

The touch driving circuit 400 may transmit touch driving signals to multiple driving electrodes included in the touch sensor layer 150, receive touch sensing signals of multiple touch nodes through multiple sensing electrodes, respectively, and detect amounts of charge change in mutual capacitance based on the touch sensing signals.

The touch driving circuit 400 may determine whether a user's touch or proximity has occurred based on the touch sensing signal of each of the touch nodes. The user's touch indicates that an object such as the user's finger or a pen touches (e.g., directly touches) a front surface of the display device 10. The user's proximity indicates that an object such as the user's finger or a pen hovers above the front surface of the display device 10.

Referring to FIG. 4, the non-display area NDA may include a dam area DMA spaced apart from the display area DA and surrounding the display area DA and a bonding area JNA disposed around the dam area DMA.

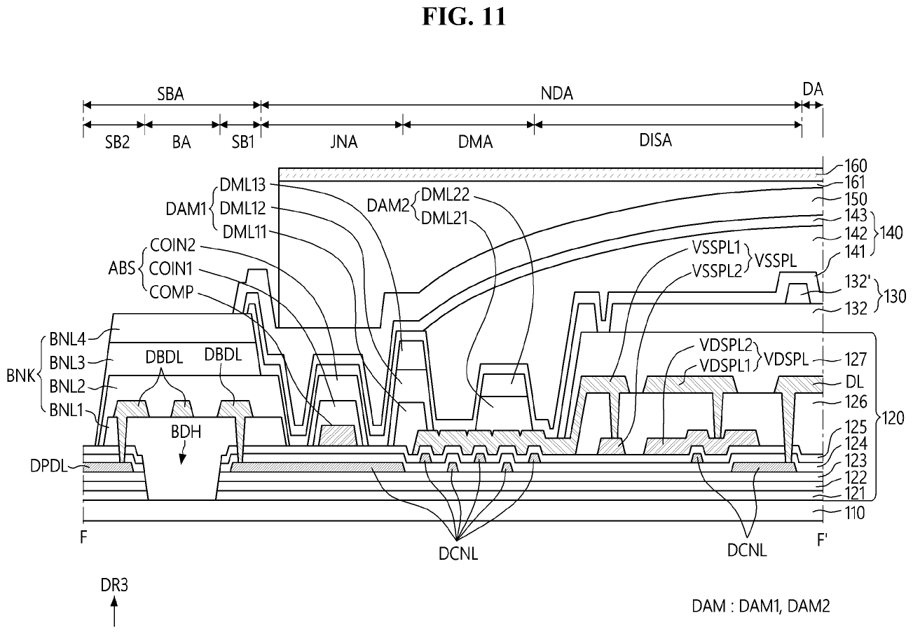

One or more dam portions DAM (see FIGS. 10 and 11) surrounding the display area DA may be arranged in the dam area DMA. The dam portions DAM may be designed to limit an area where the organic layer of the sealing layer 140 may be diffused. A valley formed between the dam portions DAM and the display area DA and between the dam portions DAM may limit the diffusion of the organic layer.

A bond between inorganic insulating materials included in the sealing layer 140 and the circuit layer 120 may be provided in the bonding area JNA.

The non-display area NDA may further include a scan driving circuit area SCDA disposed adjacent to at least one edge of the display area DA in the first direction DR1.

The circuit layer 120 may include a scan driving circuit (not illustrated) disposed in the scan driving circuit area SCDA. The scan driving circuit may supply scan signals respectively to scan lines extending in the first direction DR1 in the display area DA.

For example, the display driving circuit 200 or the circuit board 300 may supply a scan control signal to the scan driving circuit based on digital video data and timing signals.

The circuit board 300 may supply a constant voltage for generating a scan signal to the scan driving circuit.

In FIG. 4, the scan driving circuit area SCDA may be a part of the non-display area NDA which may be adjacent to both edges of the display area DA in the first direction DR1. However, this may be only an example. Although not separately illustrated, the scan driving circuit area SCDA may also be a part of the non-display area NDA which may be adjacent to any one side of the display area DA in the second direction DR2 or may be provided as separate areas which overlap parts of the display area DA.

According to an embodiment, the circuit layer 120 includes a buffer portion ABS disposed in a part of the bonding area JNA of the non-display area NDA, the bonding area JNA may be adjacent to the sub-area SBA. The buffer portion ABS may be disposed between the dam area DMA and the sub-area SBA.

In the first direction DR1, a width of the buffer portion ABS may be greater than or equal to a width of the sub-area SBA. Here, the first direction DR1 intersects a direction (i.e., the second direction DR2) in which the sub-area SBA protrudes from the main area MA.

The buffer portion ABS may be an element for preventing the pressure of a roller from becoming relatively greater in the bonding area JNA than in the display area DA in a laminating process for disposing the polarization layer 160.

The buffer portion ABS will be described in detail below.

The sub-area SBA may include a bending area BA which may be transformed into a bent shape and a first sub-area SB1 and the second sub-area SB2 which contact both sides of the bending area BA.

The first sub-area SB1 may be disposed between the main area MA and the bending area BA. A side of the first sub-area SB1 may contact the non-display area NDA of the main area MA, and the other side of the first sub-area SB1 may contact the bending area BA.

The second sub-area SB2 may be spaced apart from the main area MA with the bending area BA disposed between them. The second sub-area SB2 may be disposed on a lower surface of the substrate 110 due to the bending area BA transformed into a bent shape. The second sub-area SB2 may overlap the main area MA in a thickness direction DR3 of the substrate 110 due to the bending area BA transformed into a bent shape.

A side of the second sub-area SB2 may contact the bending area BA. The other side of the second sub-area SB2 includes a portion of an edge of the substrate 110.

The signal pads SPD and the display driving circuit 200 may be disposed in the second sub-area SB2.

The display driving circuit 200 may generate signals and voltages for driving the pixel drivers PXD of the display area DA.

The display driving circuit 200 may be provided as an integrated circuit and mounted on the second sub-area SB2 of the substrate 110 by a chip on glass (COG) method, a chip on plastic (COP) method, or an ultrasonic bonding method. However, the disclosure may not be limited thereto. For example, the display driving circuit 200 may also be mounted on the circuit board 300 by a chip on film (COF) method.

The circuit board 300 may be attached and electrically connected to the signal pads SPD of the second sub-area SB2 using an anisotropic conductive film or a low-resistance, high-reliability material such as a superabsorbent polymer (SAP).

The pixel drivers PXD of the display area DA and the display driving circuit 200 may receive digital video data, timing signals, and driving voltages from the circuit board 300.

The circuit board 300 may be a flexible printed circuit board, a printed circuit board, a flexible film such as a chip on film, or a combination thereof.

FIG. 5 is a plan view of portion B of FIG. 4.

Referring to FIG. 5, the display area DA may include the emission areas EA and a non-emission area NEA between the emission areas EA.

Each of the emission areas EA may be a unit that emits light of a wavelength band corresponding to one of two or more different colors with a luminance corresponding to an image signal.

For example, the emission areas EA may include first emission areas EA1 emitting light of a first color in a wavelength band, second emission areas EA2 emitting light of a second color in a wavelength band lower than that of the first color, and third emission areas EA3 emitting light of a third color in a wavelength band lower than that of the second color.

For example, the first color may be red in a wavelength band of about 600 to about 750 nm. The second color may be green in a wavelength band of about 480 to about 560 nm. The third color may be blue in a wavelength band of about 370 to about 460 nm. However, this may be only an example, and the respective wavelength bands of the first color, the second color and the third color according to an embodiment of the specification may not be limited to this example.

Since the emission areas EA include the first emission areas EA1, the second emission areas EA2 and the third emission areas EA3, a combination of one or more first emission areas EA1 adjacent to each other among the emission areas EA, one or more second emission areas EA2, and one or more third emission areas EA3 may form each pixel portion PX.

Each pixel portion PX may be a unit that displays various colors including white. Light of various colors displayed by each pixel portion PX may be realized through color mixing of light emitted from two or more emission areas EA included in each pixel portion PX.

For example, as illustrated in FIG. 5, the first emission areas EA1 and the third emission areas EA3 may be alternately arranged in the first direction DR1 and the second direction DR2. In addition, the second emission areas EA2 may be arranged side by side with each other in the first direction DR1 and the second direction DR2 and may neighbor the first emission areas EA1 or the third emission areas EA3 in a diagonal direction intersecting the first direction DR1 and the second direction DR2.

Each pixel portion PX may include one first emission area EA1 and one third emission area EA3 neighboring each other in the first direction DR1 and two second emission areas EA2 neighboring them in diagonal directions. However, this may be only an example, and the arrangement form of the emission areas EA and the elements of each pixel portion PX according to an embodiment may not be limited to those illustrated in FIG. 5.

FIG. 6 is schematic diagram of an equivalent circuit of a pixel driver PXD corresponding to one emission area EA among the pixel drivers PXD included in the circuit layer 120 of FIG. 3.

FIG. 6 is schematic diagram of an equivalent circuit of a pixel driver PXD in the circuit layer 120 of FIG. 3.

The circuit layer 120 of the display device 10 according to the embodiment includes the pixel drivers PXD respectively corresponding to the emission areas EA and data lines DL transmitting data signals Vdata to the pixel drivers PXD. The pixel drivers PXD of the circuit layer 120 may be electrically connected to the light emitting elements LE of the light emitting element layer 130, respectively.

The circuit layer 120 may further include first power lines VDL transmitting first power ELVDD to the pixel drivers PXD and initialization voltage lines VIL transmitting an initialization voltage Vint to the pixel drivers PXD.

The circuit layer 120 may further include scan write lines GWL transmitting scan write signals GW to the pixel drivers PXD, scan initialization lines GIL transmitting scan initialization signals GI to the pixel drivers PXD, emission control lines ECL transmitting emission control signals EC to the pixel drivers PXD, and gate control lines GCL transmitting gate control signals GC to the pixel drivers PXD.

Referring to FIG. 6, one of the pixel drivers PXD of the circuit layer 120 may include a driving transistor DT generating a driving current for driving a light emitting element LE electrically connected to the pixel driver PXD. In addition, the pixel driver PXD may further include two or more transistors ST1 through ST6 electrically connected to the driving transistor DT and at least one capacitor PC1.

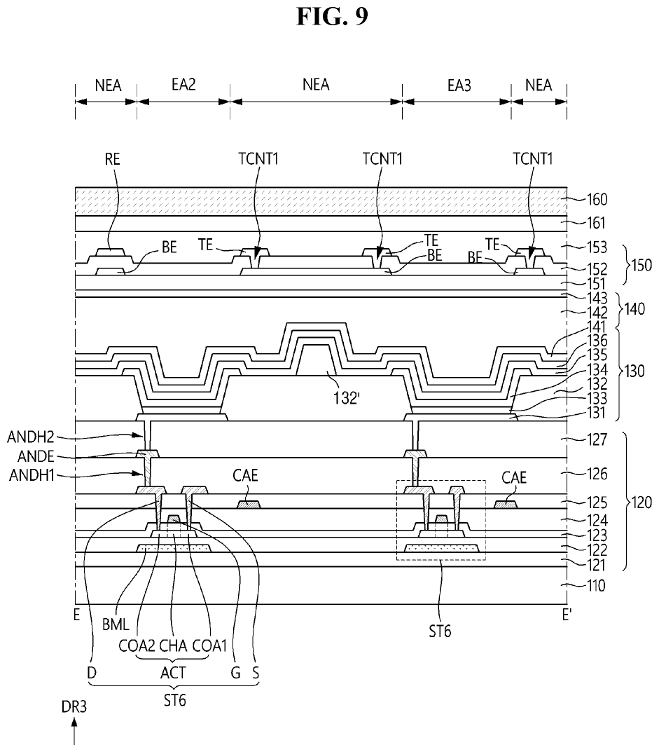

An anode 131 (see FIG. 9) of the light emitting element LE may be electrically connected to the pixel driver PXD, and a cathode 136 (see FIG. 9) of the light emitting element LE may be electrically connected to a second power line VSL that transmits second driving power ELVSS at a lower voltage level than the first power ELVDD.

The light emitting element LE may be an organic light emitting diode having a light emitting layer made of an organic light emitting material. Alternatively, the light emitting element LE may be an inorganic light emitting element having a light emitting layer made of an inorganic semiconductor. Alternatively, the light emitting element LE may be a quantum dot light emitting element having a quantum dot light emitting layer. Alternatively, the light emitting element LE may be a micro-light emitting diode.

A capacitor Cel electrically connected in parallel to the light emitting element LE may be a parasitic capacitance between the anode 131 and the cathode 136.

The driving transistor DT may be electrically connected in series to the light emitting element LE between a first power line VDL and the second power line VSL. A first electrode (e.g., a source electrode) of the driving transistor DT may be electrically connected to the first power line VDL through a fifth transistor ST5. In addition, a second electrode (e.g., a drain electrode) of the driving transistor DT may be electrically connected to the anode 131 of the light emitting element LE through a sixth transistor ST6.

The first electrode of the driving transistor DT may be electrically connected to a data line DL through a second transistor ST2.

A gate electrode of the driving transistor DT may be electrically connected to the first power line VDL through a first capacitor PC1. The first capacitor PC1 may be electrically connected between the gate electrode of the driving transistor DT and the first power line VDL.

Accordingly, the electric potential of the gate electrode of the driving transistor DT may be maintained at the first power ELVDD of the first power line VDL.

Therefore, in case that a data signal Vdata of the data line DL is transmitted to the first electrode of the driving transistor DT through the turned-on second transistor ST2, a voltage difference corresponding to the first power ELVDD and the data signal Vdata may be generated between the gate electrode of the driving transistor DT and the first electrode of the driving transistor DT.

Here, in case that the voltage difference between the gate electrode of the driving transistor DT and the first electrode of the driving transistor DT, that is, a gate-source voltage difference may be equal to or greater than a threshold voltage, the driving transistor DT may be turned on.

In case that the fifth transistor ST5 and the sixth transistor ST6 may be turned on, the driving transistor DT may be electrically connected in series to the light emitting element LE between the first power line VDL and the second power line VSL. Accordingly, a drain-source current corresponding to the data signal Vdata may be generated by the turned-on driving transistor DT and supplied as the driving current of the light emitting element LE.

Therefore, the light emitting element LE may emit light having a luminance corresponding to the data signal Vdata.

The second transistor ST2 may be electrically connected between the first electrode of the driving transistor DT and the data line DL.

A first transistor ST1 may be electrically connected between the gate electrode of the driving transistor DT and the second electrode of the driving transistor DT.

The first transistor ST1 may include multiple sub-transistors electrically connected in series. For example, the first transistor ST1 may include a first sub-transistor ST11 and a second sub-transistor ST12.

A first electrode of the first sub-transistor ST11 may be electrically connected to the gate electrode of the driving transistor DT, a second electrode of the first sub-transistor ST11 may be electrically connected to a first electrode of the second sub-transistor ST12, and a second electrode of the second sub-transistor ST12 may be electrically connected to the second electrode of the driving transistor DT.

It may be possible to prevent the electric potential of the gate electrode of the driving transistor DT from being changed by a leakage current caused by the first transistor ST1 that may not be turned on.

A gate electrode of each of the second transistor ST2, the first sub-transistor ST11, and the second sub-transistor ST12 may be electrically connected to a scan write line GWL.

Accordingly, in case that a scan write signal GW may be received through the scan write line GWL, the second transistor ST2, the first sub-transistor ST11, and the second sub-transistor ST12 may be turned on.

At this time, the data signal Vdata may be transmitted to the first electrode of the driving transistor DT through the turned-on second transistor ST2.

The gate electrode of the driving transistor DT may have the same electric potential as the second electrode of the driving transistor DT through the turned-on first sub-transistor ST11 and second sub-transistor ST12.

Accordingly, the driving transistor DT may be turned on.

A third transistor ST3 may be electrically connected between the gate electrode of the driving transistor DT and an initialization voltage line VIL.

The third transistor ST3 may include multiple sub-transistors electrically connected in series. For example, the third transistor ST3 may include a third sub-transistor ST31 and a fourth sub-transistor ST32.

A first electrode of the third sub-transistor ST31 may be electrically connected to the gate electrode of the driving transistor DT, a second electrode of the third sub-transistor ST31 may be electrically connected to a first electrode of the fourth sub-transistor ST32, and a second electrode of the fourth sub-transistor ST32 may be electrically connected to the initialization voltage line VIL.

It may be possible to prevent the electric potential of the gate electrode of the driving transistor DT from being changed by a leakage current caused by the third transistor ST3 that may not be turned on.

A gate electrode of each of the third sub-transistor ST31 and the fourth sub-transistor ST32 may be electrically connected to a scan initialization line GIL.

Accordingly, in case that a scan initialization signal GI is received through the scan initialization line GIL, the third sub-transistor ST31 and the fourth sub-transistor ST32 may be turned on, thereby initializing the electric potential of the gate electrode of the driving transistor DT to the initialization voltage Vint of the initialization voltage line VIL.

A fourth transistor ST4 may be electrically connected between the anode 131 of the light emitting element LE and the initialization voltage line VIL.

A gate electrode of the fourth transistor ST4 may be electrically connected to a gate control line GCL.

Accordingly, in case that a gate control signal GC is received through the gate control line GCL, the fourth transistor ST4 may be turned on.

At this time, the electric potential of the anode 131 of the light emitting element LE may be initialized to the initialization voltage Vint of the initialization voltage line VIL through the turned-on fourth transistor ST4.

Therefore, the light emitting element LE may be prevented from being driven by a current remaining in the anode 131.

The fifth transistor ST5 may be electrically connected between the first electrode of the driving transistor DT and the first power line VDL.

The sixth transistor ST6 may be electrically connected between the second electrode of the driving transistor DT and the anode 131 of the light emitting element LE.

A gate electrode of each of the fifth transistor ST5 and the sixth transistor ST6 may be electrically connected to an emission control line ECL.

Accordingly, in case that an emission control signal EC is received through the emission control line ECL, the fifth transistor ST5 and the sixth transistor ST6 may be turned on, thereby supplying the drain-source current of the driving transistor DT as the driving current of the element LE.

Although the driving transistor DT and the first through sixth transistors ST1 through ST6 included in the pixel driver PXD of FIG. 6 may be all N-type metal oxide semiconductor field effect transistors (MOSFETs), it should be noted that the pixel driver PXD according to the embodiment may not be limited to the illustration in FIG. 6. At least one of the driving transistor DT and the first through sixth transistors ST1 through ST6 included in the pixel driver PXD according to the embodiment may also be a P-type MOSFET.

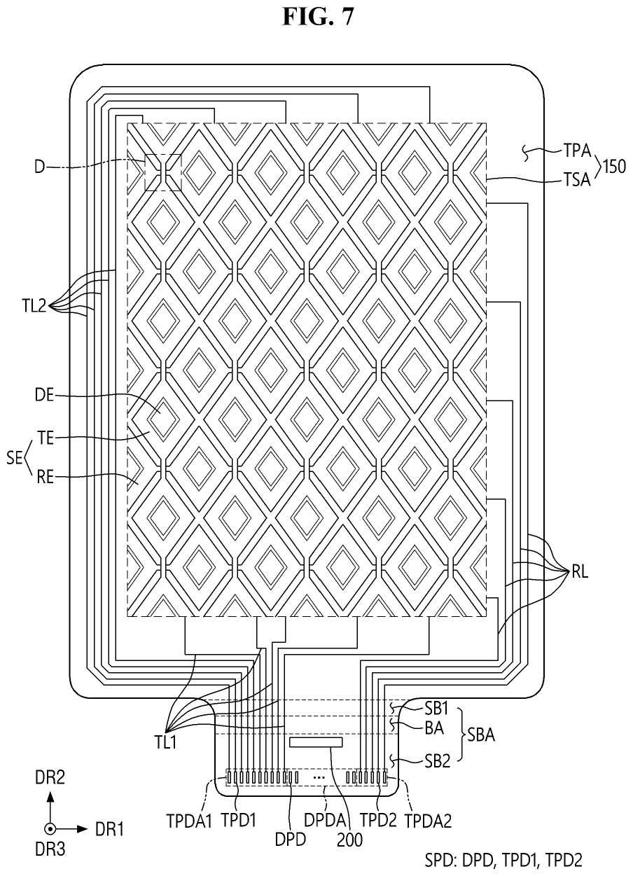

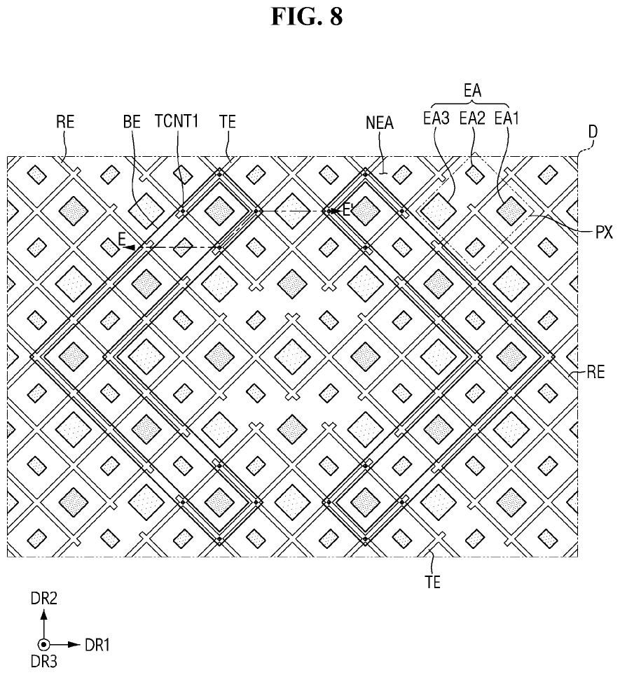

FIG. 7 is a plan view of the touch sensor layer 150 of FIG. 3. FIG. 8 is an enlarged view of portion D of FIG. 7. FIG. 9 is a schematic cross-sectional view taken along line E-E′ of FIG. 8.

FIG. 7 shows touch sensor layer 150 which is capacitive. The touch driving circuit 400 may detect a touch based on a change in capacitance. However, FIG. 7 may be only an example used for easy description, and the touch sensor layer 150 according to an embodiment may not be limited to the illustration in FIG. 7.

For ease of description, FIG. 7 illustrates only at least one of the elements of the touch sensor layer 150.

Referring to FIG. 7, the touch sensor layer 150 may be disposed in the main area MA. The touch sensor layer 150 may include a touch sensing area TSA for sensing a user's touch and a touch peripheral area TPA around the touch sensing area TSA.

The touch sensing area TSA may be wider than the display area DA and may be similar to the display area DA. Accordingly, the touch peripheral area TPA disposed around the touch sensing area TSA may be similar to the non-display area NDA disposed around the display area DA.

For example, the touch sensing area TSA may overlap the display area DA and edges of the non-display area NDA adjoining the display area DA. The touch peripheral area TPA may overlap the remaining portion of the non-display area NDA which does not correspond to the touch sensing area TSA.

The touch sensor layer 150 may include sensor electrodes SE and dummy electrodes DE which may be arranged in a matrix in the touch sensing area TSA and generate mutual capacitance. The touch sensor layer 150 may also include sensor lines SENL which may be disposed in the touch peripheral area TPA.

The sensor electrodes SE may include touch driving electrodes TE to which driving signals may be transmitted. Sensor electrodes SE may also include receiving electrodes RE for sensing voltages charged in mutual capacitance with the touch driving electrodes TE.

The sensor lines SENL may include first driving lines TL1, second driving lines TL2, and sensing lines RL.

Each of the first and second driving lines TL1 and TL2 may be electrically connected in the second direction DR2 to two or more touch driving electrodes TE among the touch driving electrodes TE.

The first driving lines TL1 may extend to the sub-area SBA from a portion of the touch peripheral area TPA, the portion of the touch peripheral area TPA being between a side of the touch sensing area TSA in the second direction DR2 and the sub-area SBA.

The second driving lines TL2 may extend from another portion of the touch peripheral area TPA in contact with another side of the touch sensing area TSA in the second direction DR2 to the sub-area SBA via a yet another portion of the touch peripheral area TPA in contact with one side of the touch sensing area TSA in the first direction DR1.

Each of the sensing lines RL may be electrically connected to two or more receiving electrodes RE electrically connected in the first direction DR1 among the receiving electrodes RE.

The receiving electrodes RE may be arranged side by side in the first direction DR1.

The receiving electrodes RE neighboring each other in the first direction DR1 may be electrically connected to each other through a protruding portion in the first direction DR1.

The touch driving electrodes TE may be arranged side by side in the second direction DR2. The touch driving electrodes TE neighboring each other in the second direction DR2 may be electrically connected to each other through bridge electrodes BE (see FIG. 8) in the second direction DR2.

Each of the touch driving electrodes TE and the receiving electrodes RE may surround a dummy electrode DE disposed in its center.

Each of the dummy electrodes DE may be spaced apart from a touch driving electrode TE or a receiving electrode RE surrounding the dummy electrode DE. The dummy electrodes DE may be kept in a floating state.

Although the touch driving electrodes TE, the receiving electrodes RE, and the dummy electrodes DE have a rhombic planar shape in FIG. 7, an embodiment may not be limited to the illustration in FIG. 7. For example, the touch driving electrode TE, the receiving electrodes RE, and the dummy electrodes DE may also have a quadrilateral shape other than a rhombus shape, a polygonal shape other than a quadrilateral shape, a circular shape, or an oval shape in a plan view.

The display panel 100 of the display device 10 according to the embodiment may include the signal pads SPD disposed in the second sub-area SB2 and electrically connected to the circuit board 300.

The signal pads SPD may include display signal pads DPD for transmitting and receiving signals for driving the circuit layer 120 and touch signal pads TPD1 and TPD2 for transmitting and receiving signals for driving the touch sensor layer 150.

For example, the second sub-area SB2 may include a display pad area DPDA adjacent to the display driving circuit 200 and a first touch pad area TPDA1 and a second touch pad area TPDA2 disposed on both sides of the display pad area DPDA.

The display pads DPD for transmitting and receiving signals to and from the circuit layer 120 or the display driving circuit 200 may be disposed in the display pad area DPDA.

First touch pads TPD1 electrically connected to the first driving lines TL1 and the second driving lines TL2, respectively, may be disposed in the first touch pad area TPDA1.

Second touch pads TPD2 electrically connected to the sensing lines RL, respectively, may be disposed in the second touch pad area TPDA2.

Referring to FIG. 8, the bridge electrodes BE may be provided as a first touch sensor layer, and the touch driving electrodes TE and the receiving electrodes RE may be provided as a second touch sensor layer.

The touch driving electrodes TE and the receiving electrodes RE may be spaced apart from each other.

Although the bridge electrodes BE bent at least once may be illustrated in FIG. 8, the shape of the bridge electrodes BE according to an embodiment may not be limited to that illustrated in FIG. 8.

The touch driving electrodes TE neighboring each other in the second direction DR2 may be electrically connected to each other through two or more bridge electrodes BE. The reliability of electrical connection between the touch driving electrodes TE can be improved.

Although two bridge electrodes BE parallel to each other may be disposed between the touch driving electrodes TE neighboring each other in the second direction DR2 in FIG. 8, an embodiment may not be limited to the illustration in FIG. 8.

The bridge electrodes BE may be electrically connected to the touch driving electrodes TE through touch contact apertures TCNT1.

The touch driving electrodes TE, the receiving electrodes RE, and the bridge electrodes BE may have a mesh or net structure in a plan view. The dummy electrodes DE may also have a mesh or net structure in a plan view. A width of a portion of each emission area EA which overlaps a touch driving electrode TE, a receiving electrode RE, a dummy electrode DE, and a bridge electrode BE may be reduced. Accordingly, a decrease in light emission efficiency due to the touch driving electrodes TE, the receiving electrodes RE, the dummy electrodes DE, and the bridge electrodes BE can be reduced.

The emission areas EA may include the first emission areas EA1 emitting light of the first color, the second emission areas EA2 emitting light of the second color in a wavelength band lower than that of the first color, and the third emission areas EA3 emitting light of the third color in a wavelength band lower than that of the second color. For example, the first color, second color, and third color may be red, green, and blue, respectively.

The first emission areas EA1 and the third emission areas EA3 may be alternately arranged in the first direction DR1 and the second direction DR2.

The second emission areas EA2 may neighbor the first emission areas EA1 and the third emission areas EA3 in directions oblique to the first direction DR1 and the second direction DR2. The second emission areas EA2 may be arranged side by side in the first direction DR1 and the second direction DR2.

Although each of the emission areas EA has a rhombic or rectangular planar shape in FIG. 8, the planar shape of each of the emission areas EA according to an embodiment may not be limited to that illustrated in FIG. 8. Each of the emission areas EA may also have a polygonal shape other than a quadrilateral shape, a circular shape, or an oval shape in plan view.

As illustrated in FIG. 8, in case that the first color of the first emission areas EA1, the second color of the second emission areas EA2, and the third color of the third emission areas EA3 may be red, green, and blue, respectively, the third emission areas EA3 may be wider than the first emission areas EA1, and the second emission areas EA2 may be narrower than the first emission areas EAL. However, this may be only an example, and the width of each of the emission areas EA may not be limited to that illustrated in FIG. 8.

Referring to FIG. 9, the display panel 100 of the display device 10 according to the embodiment may include the substrate 110, the circuit layer 120 on the substrate 110, the light emitting element layer 130 on the circuit layer 120, the sealing layer 140 on the light emitting element layer 130, and the touch sensor layer 150 on the sealing layer 140.

The substrate 110 may be made of a flexible material that can be bent, folded, or rolled.

The substrate 110 may be made of an insulating material such as polymer resin. For example, the substrate 110 may be made of polyimide.

The circuit layer 120 may include the pixel drivers PXD respectively corresponding to the emission areas EA.

Each of the pixel drivers PXD may include two or more transistors DT and ST1 through ST6 (see FIG. 6) and at least one capacitor PC1 (see FIG. 6).

The circuit layer 120 may include the pixel drivers PXD, conductive layers for forming the lines GWL, GIL, ECL, GCL, DL, VIL, VDL and VSL (see FIG. 6) electrically connected to the pixel drivers PXD, and insulating layers 121 through 127 disposed between the conductive layers.

The circuit layer 120 includes a semiconductor layer (ACT) disposed on the substrate 110, a first gate insulating layer 123 disposed on the substrate 110 covering the semiconductor layer (ACT) and including an inorganic insulating material, a first conductive layer (G) disposed on the first gate insulating layer 123, a second gate insulating layer 124 disposed on the first gate insulating layer 123 covering the first conductive layer (G) and including an inorganic insulating material, a second conductive layer (CAE) disposed on the second gate insulating layer 124, an interlayer insulating layer 125 disposed on the second gate insulating layer 124 covering the second conductive layer (CAE) and including an inorganic insulating material, a third conductive layer (S and D) disposed on the interlayer insulating layer 125, a first planarization layer 126 disposed on the interlayer insulating layer 125 covering the third conductive layer (S and D) and including an organic insulating material, a fourth conductive layer (ANDE) disposed on the first planarization layer 126, and a second planarization layer 127 disposed on the first planarization layer 126 covering the fourth conductive layer (ANDE) and including an organic insulating material.

The first planarization layer 126 includes a first planarization layer corresponding to the display area DA. In addition, the second planarization layer 127 includes a second planarization layer corresponding to the display area DA and covering the first planarization layer 126. In the following description, the first planarization layer 126 may be referred to by the same reference numeral as the first planarization layer, and the second planarization layer 127 may be referred to by the same reference numeral as the second planarization layer.

The semiconductor layer may include active layers ACT of the transistors DT and ST1 through ST6. The semiconductor layer may include polycrystalline silicon, monocrystalline silicon, low-temperature polycrystalline silicon, amorphous silicon, or an oxide semiconductor material.

The first conductive layer on the first gate insulating layer 123 may include gate electrodes G of the transistors DT and ST1 through ST6.

The second conductive layer on the second gate insulating layer 124 may include first capacitor electrodes CAE of capacitors PC1.

The third conductive layer on the interlayer insulating layer 125 may include source electrodes S of the transistors DT and ST1 through ST6 and drain electrodes D of the transistors DT and ST1 through ST6.

The fourth conductive layer on the first planarization layer 126 may include anode connection electrodes ANDE respectively corresponding to the emission areas EA.

The circuit layer 120 may further include a first buffer layer 121 for blocking oxygen or moisture permeated through the substrate 110, light blocking layers BML for blocking light transmitted through the substrate 110, and a second buffer layer 122 covering the light blocking layers BML. The semiconductor layer may be disposed on the second buffer layer 122.

Each of the first buffer layer 121 and the second buffer layer 122 may include an inorganic insulating material.

For example, each of the first buffer layer 121 and the second buffer layer 122 may be a multilayer in which one or more inorganic layers are selected from a silicon nitride layer, a silicon oxynitride layer, a silicon oxide layer, a titanium oxide layer, and an aluminum oxide layer may be alternately stacked on each other.

The light blocking layers BML may be designed to prevent leakage current of the active layers ACT caused by light introduced through the substrate 110. To this end, each of the light blocking layers BML may overlap at least a channel region CHA of an active layer ACT on the second buffer layer 122. Alternatively, each of the light blocking layers BML may overlap the entire active layer ACT.

Each of the light blocking layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. Alternatively, each of the light blocking layers BML may be an organic layer including a black pigment.

Each of the two or more transistors DT and ST1 through ST6 included in each pixel driver PXD may include a light blocking layer BML on the substrate 110, an active layer ACT on the second buffer layer 122 covering the light blocking layer BML, a gate electrode G disposed on the first gate insulating layer 123 covering the active layer ACT, and a source electrode S and a drain electrode D disposed on the interlayer insulating layer 125.

The active layer ACT may include the channel region CHA that generates a channel according to a potential difference and a first electrode region COA1 and a second electrode region COA2 disposed on both sides of the channel region CHA.

In case that the active layer ACT includes polycrystalline silicon or an oxide semiconductor material, the first electrode region COA1 and the second electrode region COA2 may be regions made conductive by ion doping.

Each of the first gate insulating layer 123, the second gate insulating layer 124, and the interlayer insulating layer 125 includes an inorganic insulating material. For example, each of the first gate insulating layer 123, the second gate insulating layer 124, and the interlayer insulating layer 125 may be made of an inorganic layer such as a silicon nitride layer, a silicon oxynitride layer, a silicon oxide layer, a titanium oxide layer, an aluminum oxide layer, or a combination thereof. Here, the interlayer insulating layer 125 may be made of a silicon nitride layer.

The gate electrode G may overlap the channel region CHA of the active layer ACT in the third direction DR3.

The first conductive layer including the gate electrodes G of the transistors DT and ST1 through ST6 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second conductive layer including the first capacitor electrodes CAE of the capacitors PC1 may be a single layer or a multilayer made of any one or more of molybdenum (Mo), aluminum (Al), chromium (Cr), gold (Au), titaniurn (Ti), nickel (Ni), neodymium (Nd), copper (Cu), and alloys thereof.

The third conductive layer including the source electrodes S of the transistors DT and ST1 through ST6 and the drain electrodes D of the transistors DT and ST1 through ST6 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The fourth conductive layer including the anode connection electrodes ANDE may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

Here, each of the third conductive layer and the fourth conductive layer may include a triple layer including a low-resistance metal layer such as molybdenum (Mo), aluminum (Al), copper (Cu) or nickel (Ni) and anti-diffusion metal layers such as titanium (Ti) disposed on both surfaces of the low-resistance metal.

Each of the first planarization layer 126 and the second planarization layer 127 may include an organic insulating material for planarization of the circuit layer 120.

For example, each of the first planarization layer 126 and the second planarization layer 127 may be made of an organic layer such as acryl resin, epoxy resin, phenolic resin, polyamide resin, or polyimide resin.

In FIG. 9, the transistors DT and ST1 through ST6 of the circuit layer 120 have a top gate structure in which the gate electrode G may be located above the active layer ACT. However, an embodiment may not be limited to the illustration in FIG. 9. The transistors DT and ST1 through ST6 of the circuit layer 120 may also have a bottom gate structure in which the gate electrode G may be located below the active layer ACT or a double gate structure in which the gate electrode G may be located both above and below the active layer ACT.

The light emitting element layer 130 may be disposed on the second planarization layer 127 of the circuit layer 120 and includes the light emitting elements LE respectively corresponding to the emission areas EA.

The light emitting element layer 130 may include the anodes 131 disposed on the second planarization layer 127 of the circuit layer 120 and respectively corresponding to the emission areas EA, a pixel defining layer 132 disposed on the second planarization layer 127 of the circuit layer 120, corresponding to the non-emission area NEA between the emission areas EA and covering edges of the anodes 131, a spacer layer 132′ disposed on a portion of the pixel defining layer 132, first common layers 133 respectively disposed on the anodes 131, light emitting layers 134 respectively disposed on the first common layers 133, a second common layer 135 disposed on the pixel defining layer 132, the spacer layer 132′ and the light emitting layers 134, and the cathode 136 disposed on the second common layer 135.

Here, each of the light emitting elements LE may include a structure in which a first common layer 133, a light emitting layer 134 and the second common layer 135 made of organic materials may be disposed between an anode 131 and the cathode 136 facing each other.

The anodes 131 may be electrically connected to the pixel drivers PXD of the circuit layer 120 through the anode connection electrodes ANDE, respectively.

In each emission area EA, an anode connection electrode ANDE may be electrically connected to the drain electrode D of the sixth transistor ST6 of a pixel driver PXD through a first anode connection aperture ANDH1 penetrating the first planarization layer 126, and an anode 131 may be electrically connected to the anode connection electrode ANDE through a second anode connection aperture ANDH2 penetrating the second planarization layer 127.

Since the anode 131 may be electrically connected to the pixel driver PXD of each emission area EA, it may also be referred to as a pixel electrode.

The anodes 131 may be made of a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/A PC/ITO) of an APC alloy and indium tin oxide. The APC alloy may be an alloy of silver (Ag), palladium (Pd), and copper (Cu).

The first common layers 133 may correspond to the emission areas EA, respectively. Each of the first common layers 133 may include a hole transport layer. Alternatively, each of the first common layers 133 may further include a hole injection layer between an anode 131 and the hole transport layer.

The light emitting layers 134 may correspond to the emission areas EA, respectively.

The light emitting layer 134 of each first emission area EA1, the light emitting layer 134 of each second emission area EA2, and the light emitting layer 134 of each third emission area EA3 may include organic light emitting materials having different materials or contents.

For example, the light emitting layer 134 may be made of an organic light emitting material that converts electron-hole pairs into light.

The organic light emitting material may include a host material and a dopant. The dopant may include a phosphorescent material or a fluorescent material.

The light emitting layer 134 of each first emission area EA1 emitting light of the first color may include a host material of carbazole biphenyl (CBP) or 1,3-bis (carbazol-9-yl) (mCP).

A dopant of the light emitting layer 134 of each first emission area EA1 may include one or more phosphorescent materials selected from bis(1-phenylisoquinoline)acetylacetonate iridium (PIQIr(acac)), bis(1-phenylquinoline)acetylacetonate iridium (PQIr(acac)), tris (1-phenylquinoline)iridium (PQIr) and octaethylporphyrin platinum (PtOEP) or may be a fluorescent material including PBD:Eu(DBM)3(Phen) or perylene.

The light emitting layer 134 of each second emission area EA2 emitting light of the second color in a wavelength band lower than that of the first color may include a host material of CBP or mCP.

A dopant of the light emitting layer 134 of each second emission area EA2 may be a phosphorescent material including Ir(ppy)3(fac tris(2-phenylpyridine)iridium) or a fluorescent material including tris(8-hydroxyquinolino)aluminum (Alq3).

The light emitting layer 134 of each third emission area EA3 emitting light of the third color in a wavelength band lower than that of the second color may include a host material of CBP or mCP.

A dopant of the light emitting layer 134 of each third emission area EA3 may be a phosphorescent material including (4,6-F2ppy)2Irpic or L2BD111.

The above description of the organic light emitting material of the light emitting layer 134 may be only an example, and the material of the light emitting layer 134 according to an embodiment may not be limited to the above description.

The second common layer 135 may correspond to the entire display area DA including the emission areas EA. The second common layer 135 may include an electron transport layer. Alternatively, the second common layer 135 may further include an electron injection layer between the cathode 136 and the electron transport layer.

The cathode 136 may correspond to the entire display area DA including the emission areas EA. The cathode 136 may be electrically connected to the second power line VSL (see FIG. 6) which transmits the second power ELVSS.

Since the cathode 136 corresponds to the emission areas EA as a whole, it may also be referred to as a common electrode.

The cathode 136 may be made of a transparent conductive material (TCO) capable of transmitting light, such as ITO or IZO, or a semi-transmissive conductive material such as magnesium (Mg), silver (Ag) or an alloy of Mg and Ag. In case that the cathode 136 may be made of a semi-transmissive conductive material, an improvement in light output efficiency by a microcavity can be expected.

The sealing layer 140 may be designed to block the permeation of oxygen or moisture into the light emitting element layer 130 and reduce electrical or physical shock to the circuit layer 120 and the light emitting element layer 130.

The sealing layer 140 may include a first sealing layer 141 disposed on the circuit layer 120 covering the light emitting element layer 130 and including an inorganic insulating material, a second sealing layer 142 disposed on the first sealing layer 141, overlapping the light emitting element layer 130 and including an organic insulating material, and a third sealing layer 143 disposed on the first sealing layer 141, covering the second sealing layer 142 and including an inorganic insulating material.

The second sealing layer 142 may be made of an organic insulating material such as acryl resin, epoxy resin, phenolic resin, polyamide resin, polyimide resin, or a combination thereof.

The second sealing layer 142 may be prepared by dropping an organic material in a liquid state onto the first sealing layer 141, spreading the organic material widely to cover the display area DA, and curing the spread organic material.

Therefore, according to the first embodiment, the display panel 100 of the display device 10 may further include a dam DAM (see FIGS. 10 and 11) for limiting a range in which the organic material of the second sealing layer 142 spreads. The dam DAM may be disposed in the dam area DMA of the non-display area NDA.

The second sealing layer 142 spreads to the dam area DAM in which at least one dam DAM may be disposed. Therefore, the third sealing layer 143 may be bonded to the first sealing layer 141 in the bonding area JNA disposed around the dam area DMA of the non-display area NDA.

Each of the first sealing layer 141 and the third sealing layer 143 may have a structure in which one or more inorganic layers selected from a silicon nitride layer, a silicon oxynitride layer, a silicon oxide layer, a titanium oxide layer, and an aluminum oxide layer may be stacked on each other.

The touch sensor layer 150 may be disposed on the sealing layer 140.

According to the first embodiment, the touch sensor layer 150 may be disposed on the third sealing layer 143 of the sealing layer 140.

The touch sensor layer 150 may include a third buffer layer 151 disposed on the sealing layer 140, the bridge electrodes BE disposed on the third buffer layer 151, a sensor insulating layer 152 covering the bridge electrodes BE, the touch driving electrodes TE and the receiving electrodes RE disposed on the sensor insulating layer 152, and an overcoat layer 153 covering the touch driving electrodes TE and the receiving electrodes RE.

Each of the third buffer layer 151 and the sensor insulating layer 152 may have a structure in which one or more inorganic layers selected from a silicon nitride layer, a silicon oxynitride layer, a silicon oxide layer, a titanium oxide layer, and an aluminum oxide layer may be stacked on each other.

The overcoat layer 153 may be made of an organic material that can be disposed by a low-temperature process. For example, the overcoat layer 153 may be made of a negative photoresist material.

Each of the bridge electrodes BE, the touch driving electrodes TE, and the receiving electrodes RE may be a single layer or a multilayer made of any one or more of molybdenumi (Mo), aluminum (Al), chromium (Cr), gold (Au), titanium (Ti), nickel (Ni), neodymium (Nd), copper (Cu), and alloys thereof.

The dummy electrode DE disposed inside each of the touch driving electrodes TE and the receiving electrodes RE, the first and second driving lines TL1 and TL2 electrically connected to the touch driving electrodes TE, the sensing lines RL electrically connected to the receiving electrodes RE, and the touch driving electrodes TE and the receiving electrodes RE may be disposed on a same layer.

The touch driving electrodes TE may be electrically connected to the bridge electrodes BE through the touch contact apertures TCNT1 penetrating the sensor insulating layer 152.

The touch driving electrodes TE, the receiving electrodes RE, the dummy electrodes DE, the first driving lines TL1, the second driving lines TL2, and the sensing lines RL may have a structure including a low reflection layer. The amount of external light emitted after being reflected inside the display panel 100 (i.e., reflection of external light) can be reduced.

The display panel 100 of the display device 10 according to the embodiment may further include a fourth buffer layer 161 disposed between the polarization layer 160 and the overcoat layer 153.

In an embodiment, the fourth buffer layer by be omitted and the polarization layer 160 may be disposed on the overcoat layer 153 of the touch sensor layer 150 (not illustrated).

FIG. 10 is a plan view of portion C of FIG. 4 according to the first embodiment. FIG. 11 is a schematic cross-sectional view taken along line F-F′ of FIG. 10 according to the first embodiment.

Referring to FIG. 10, the circuit layer 120 of the display panel 100 of the display device 10 according to the first embodiment may include the data lines DL transmitting data signals Vdata to the pixel drivers PXD and data connection lines disposed in the non-display area NDA, the data connection lines DCNL being electrically connected to the data lines DL, respectively, and extending to the first sub-area SB1.

Since the data connection lines DCNL extend to the dam area DMA and the bonding area JNA, they may be included in the first conductive layer or the second conductive layer disposed under the interlayer insulating layer 125.

According to the first embodiment, the circuit layer 120 may further include data bending lines DBDL disposed in the bending area BA, electrically connected to the data connection lines DCNL, respectively, the data bending lines DBDL extending to the second sub-area SB2.

The circuit layer 120 may further include data pad lines DPDL disposed in the second sub-area SB2 and electrically connected to the data bending lines DBDL, respectively. The data pad lines DPDL may be electrically connected to output terminals (not illustrated) of the display driving circuit 200, respectively.

Therefore, the data lines DL may be electrically connected to the output terminals of the display driving circuit 200 through the data pad lines DPDL, the data bending lines DBDL, and the data connection lines DCNL, respectively.

The circuit layer 120 may further include a first power supply line VDSPL and a second power supply line VSSPL disposed in the non-display area NDA and respectively transmitting the first power ELVDD and the second power ELVSS.

The non-display area NDA may further include a dam separation area DISA disposed between the display area DA and the dam area DMA. The first power supply line VDSPL and the second power supply line VSSPL may be disposed in the dam separation area DISA. In addition, at least the second power supply line VSSPL among the first power supply line VDSPL and the second power supply line VSSPL may surround the display area DA.

The first power supply line VDSPL may include a first power main line VDSPL1 made of a portion of the fourth conductive layer and a first power sub-line VDSPL2 made of a portion of the third conductive layer.

Similarly, the second power supply line VSSPL may include a second power main line VSSPL1 made of a portion of the fourth conductive layer and a second power sub-line VSSPL2 made of a portion of the third conductive layer.

The second power main line VSSPL1 may extend to the dam area DMA.

The circuit layer 120 may further include first power connection lines VDCNL disposed in the dam area DMA and the bonding area JNA, electrically connected to the first power supply line VDSPL, the first power connection lines VDCNL extending to the first sub-area SB1. The circuit layer may also include first power bending lines VDBDL disposed in the bending area BA and electrically connected to the first power connection lines VDCNL. The circuit layer 120 may also include first power pad lines VDPDL disposed in the second sub-area SB2, electrically connected to the first power bending lines VDBDL, the first power pad lines VDPDL extending to at least one of the signal pads SPD. Therefore, the first power supply line VDSPL may be electrically connected to the circuit board 300 through the first power connection lines VDCNL, the first power bending lines VDBDL, the first power pad lines VDPDL, and at least one of the signal pad SPD.

The circuit layer 120 may further include second power connection lines VSCNL disposed in the dam area DMA and the bonding area JNA, the second power connection lines VSCNL may be electrically connected to the second power supply line VSSPL, the second power connection lines VSCNL may extend to the first sub-area SB1. The circuit layer 120 may also include second power bending lines VSBDL disposed in the bending area BA and electrically connected to the second power connection lines VSCNL. The circuit layer 120 may also include second power pad lines VSPDL disposed in the second sub-area SB2, the second power pad lines VSPDL may be electrically connected to the second power bending lines VSBDL, the second power pad lines VSPLL may extend to at least one other of the signal pads SPD. Therefore, the second power supply line VSSPL may be electrically connected to the circuit board 300 through the second power supply connection lines VSCNL, the second power bending lines VSBDL, the second power pad lines VSPDL, and at least one other of the signal pads SPD.

The circuit layer 120 according to the first embodiment includes the buffer portion ABS (see FIG. 4) disposed in a part of the bonding area JNA which may be adjacent to the sub-area SBA. The buffer portion ABS may include a compensation pattern layer COMP disposed on the interlayer insulating layer 125.

The buffer portion ABS including the compensation pattern layer COMP may be spaced apart from each of the dam area DMA and the sub-area SBA.

Referring to FIG. 11, the buffer portion ABS of the bonding area JNA according to the first embodiment may include the compensation pattern layer COMP disposed on the interlayer insulating layer 125 and one or more compensation insulating layers COIN1 and COIN2 covering the compensation pattern layer COMP.

The compensation pattern layer COMP may be included in the third conductive layer along with the first power sub-line VDSPL2 and the second power sub-line VSSPL2.

The compensation pattern layer COMP may be spaced apart from each of the dam area DMA and the sub-area SBA.

Accordingly, the compensation pattern layer COMP may be spaced apart from one or more dam portions DAM disposed in the dam area DMA, and the compensation pattern layer may be spaced apart from a bank BNK disposed in the sub-area SBA.

The first power supply line VDSPL and the second power supply line VSSPL disposed in the dam separation area DISA and the dam area DMA of the non-display area NDA may be spaced apart from the compensation pattern layer COMP of the buffer portion ABS.

The first compensation insulating layer COIN1 may cover the compensation pattern layer COMP. The first compensation insulating layer COIN1 and the first planarization layer 126 may be a same layer. The second compensation insulating layer COIN2 may be disposed on the first compensation insulating layer COIN1. The second compensation insulating layer COIN2 and the second planarization layer 127 may be a same layer.

The polarization layer 160 may overlap the light emitting element layer 130 of the display area DA and extend to the non-display area NDA to overlap the buffer portion ABS.

As described above and according to the first embodiment, the buffer portion ABS including the compensation pattern layer COMP and the compensation insulating layers COIN1 and COIN2 may be disposed in the bonding area JNA.

Accordingly, the interlayer insulating layer 125 may be partially covered by the buffer portion ABS in a part of the bonding area JNA between the sub-area SBA and the dam area DMA. Therefore, the interlayer insulating layer 125 can be prevented from being entirely damaged by a process of disposing the fourth conductive layer.

A width of a valley formed between the bank BNK of the sub-area SBA and the dam portions DAM of the dam area DMA may be reduced by the buffer portion ABS. Due to the buffer portion ABS, a valley may be formed that does not occupy an entirety of the bonding area JNA between the sub-area SBA and the dam area DMA, but instead may be formed only between the bank BNK of the sub-area SBA and the buffer portion ABS and between the dam portions DAM of the dam area DMA and the buffer portion ABS. Since the valleys formed in parts of the bonding area JNA between the sub-area SBA and the dam area DMA have a relatively small width, they may be filled readily with the overcoat layer 153 (see FIG. 9) of the touch sensor layer 150 to produce an approximately flat upper surface.

Therefore, since the polarization layer 160 can be disposed on an approximately flat surface in the bonding area JNA between the sub-area SBA and the dam area DMA, a part where the pressure of the roller may be relatively high in the laminating process for disposing the polarization layer 160 can be eliminated. Accordingly, damage to the circuit layer 120 due to the laminating process can be reduced, thereby improving the quality reliability and lifespan of the display device 10.

As illustrated in FIG. 11, the first conductive layer on the first gate insulating layer 123 of the circuit layer 120 may further include at least one of the data connection lines DCNL of the non-display area NDA.

The second conductive layer on the second gate insulating layer 124 may further include another one of the data connection lines DCNL of the non-display area NDA.

The first conductive layer on the first gate insulating layer 123 or the second conductive layer on the second gate insulating layer 124 may further include the data pad lines DPDL of the second sub-area SB2.

The third conductive layer on the interlayer insulating layer 125 may include the first and second power sub-lines VDSPL2 and VSSPL2 of the dam separation area DISA and the compensation pattern layer COMP of the bonding area JNA.

The fourth conductive layer on the first planarization layer 126 may include the data lines DL of the display area DA, the first and second power main lines VDSPL1 and VSSPL1 of the non-display area NDA, and the data bending lines DBDL of the bending area BA.

The second power main line VSSPL1 may extend to the dam area DMA and overlap the dam portions DAM.

One or more dam portions DAM may be arranged in the dam area DMA, and each of the dam portions DAM may include a structure in which two or more dam layers may be stacked on each other.

Each of the dam layers may be made of an organic layer. Each of the dam layers and one of the first planarization layer 126, the second planarization layer 127, the pixel defining layer 132, and the spacer layer 132′ may be a same layer.

For example, the dam area DMA may include a first dam portion DAM1 and a second dam portion DAM2 disposed between the first dam portion DAM1 and the display area DA.

The first dam portion DAM1 may include a structure in which three dam layers DML11 through DML13 may be stacked on each other. In the first dam portion DAM1, a first dam layer DML11 and the second planarization layer 127 may be a same layer, a second dam layer DML12 and the pixel defining layer 132 may be a same layer, and a third dam layer DML13 and the spacer layer 132′ may be a same layer.

The second dam portion DAM2 may include a structure in which two dam layers DML21 and DML22 may be stacked on each other. In the second dam portion DAM2, a first dam layer DML21 and the pixel defining layer 132 may be a same layer, and a second dam layer DML22 and the spacer layer 132′ may be a same layer.

Here, the pixel defining layer 132 and the spacer layer 132′ may be formed together through a mask process using a halftone mask.

Since the dam portions DAM disposed in the dam area DMA may be spaced apart from the display area DA, the organic layers 126, 127 and 132 formed between the dam area DMA and the display area DA and between the dam portions DAM may be removed to form valleys. Accordingly, the first sealing layer 141 of the sealing layer 140 may be bonded onto the interlayer insulating layer 125 of the circuit layer 120 in an area between the dam portions DAM of the dam area DMA.

The organic layers 126, 127 and 132 may be removed from the bonding area JNA disposed around the dam area DMA, except for the buffer portion ABS. As a result, the interlayer insulating layer 125 may be exposed. Accordingly, the first sealing layer 141 of the sealing layer 140 may also be bonded onto the interlayer insulating layer 125 of the circuit layer 120 in the bonding area JNA excluding the buffer portion ABS.

Since the second sealing layer 142 of the sealing layer 140 may be disposed within an area surrounded by the dam portions DAM of the dam area DMA, the third sealing layer 143 of the sealing layer 140 may be bonded onto the first sealing layer 141 in the bonding area JNA.

Thus, a sealing structure including inorganic materials bonded together may be provided in the dam area DMA and the bonding area JNA.

In case that the bending area BA may be bent, cracks may be generated in inorganic layers that may be relatively vulnerable to bending stress.

To prevent this, the display panel 100 of the display device 10 according to the first embodiment may further include a bending hole (or bending aperture) BDH disposed in the bending area BA and penetrating the first gate insulating layer 123, the second gate insulating layer 124 and the interlayer insulating layer 125. The bank BNK may cover the bending aperture BDH.

The bending aperture BDH may penetrate all of the inorganic layers disposed on the substrate 110 in the bending area BA. The bending aperture BDH may further penetrate the first buffer layer 121 and the second buffer layer 122.

The bank BNK may be designed to cover the bending aperture BDH and protect the data bending lines DBDL of the bending area BA.

The bank BNK may include a structure in which bank layers BNL1 through BNL4 made of organic layers may be stacked on each other.

The bank BNK may include a first bank layer BNL1 which may be a part of the first planarization layer 126 and may cover the bending aperture BDH, a second bank layer BNL2 which may be a part of the second planarization layer 127 and may cover the first bank layer BNL1, a third bank layer BNL3 which may be disposed on the second bank layer BNL2, and a fourth bank layer BNL4 which may be disposed on the third bank layer BNL3. The third bank layer BNL3 and the pixel defining layer 132 may be a same layer, and the fourth bank layer BNL4 and the spacer layer 132′ may also be a same layer.

Since the data bending lines DBDL of the bending area BA may be included in the fourth conductive layer, they may be covered by the second bank layer BNL2 which may be a part of the second planarization layer 127.

According to the first embodiment, in order to dispose contact apertures for electrical connection between the lines of the bending area BA and the lines of the first sub-area SB1 and contact apertures for electrical connection between the lines of the bending area BA and the lines of the second sub-area SB2, the bank BNK may extend to each of the first sub-area SB1 and the second sub-area SB2.

According to the first embodiment, in order to lower a step height of the bank BNK at a boundary between the bonding area JNA and the first sub-area SB1, a portion of each of the first bank layer BNL1 and the second bank layer BNL2 of the bank BNK may extend to the bonding area JNA of the non-display area NDA and thus overlap the polarization layer 160.

Unlike in the first embodiment, the bank BNK may also be disposed only in the sub-area SBA.

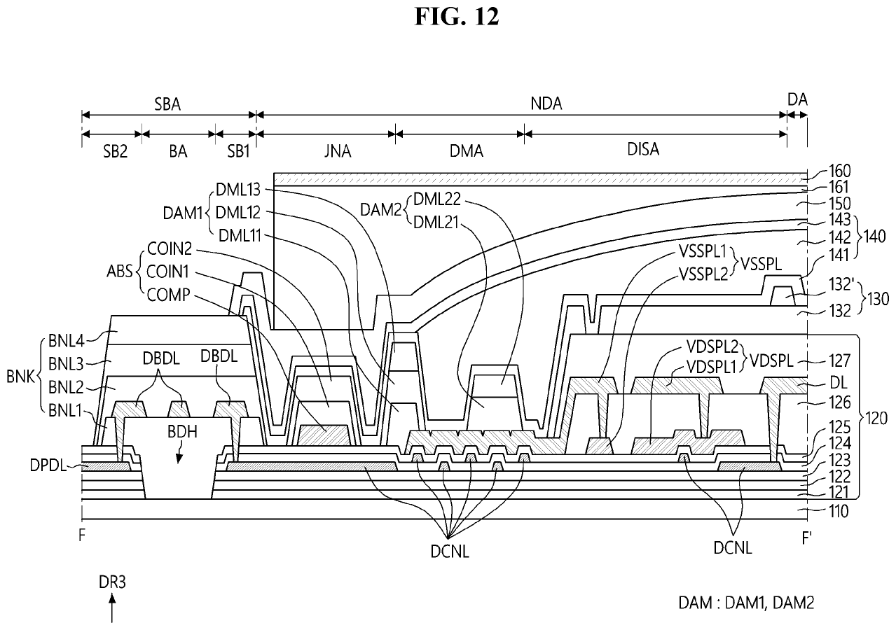

FIG. 12 is a schematic cross-sectional view taken along line F-F′ of FIG. 10 according to a second embodiment.

Referring to FIG. 12, a display device 10 according to the second embodiment may be substantially the same as the first embodiment of FIGS. 10 and 11 except that a bank BNK of a sub-area SBA extends into a first sub-area SB1 but may be spaced apart from a bonding area JNA of a non-display area NDA. Thus, any redundant description will be omitted below.

According to the second embodiment, the bank BNK may be limited within the sub-area SBA and does not extend to the bonding area JNA of the non-display area NDA. Therefore, a width of a buffer portion ABS in the bonding area JNA may be greater than that of the first embodiment. Accordingly, since a roller can be more firmly supported by the buffer portion ABS in a laminating process for disposing a polarization layer 160, inorganic insulating materials and conductive layers in the bonding area JNA can be more securely protected.

According to the second embodiment, the polarization layer 160 may be spaced apart from the bank BNK of the sub-area SBA.

As illustrated in FIG. 12, the polarization layer 160 may overlap an edge of the bank BNK at a boundary between the first sub-area SB1 and the non-display area NDA. The polarization layer 160 can be more firmly attached. In addition, since a step height may be lowered by the buffer portion ABS, a relative increase in the pressure of the roller in the bonding area JNA can be prevented, thereby preventing damage to lines and insulating layers disposed in the bonding area JNA.

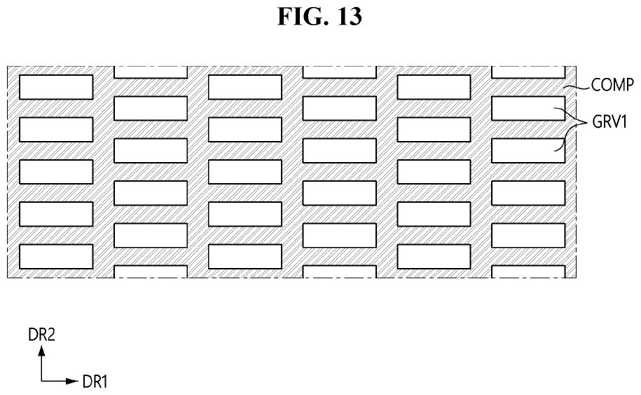

As in a third embodiment below, a compensation pattern layer COMP of the buffer portion ABS may have a mesh shape in which grooves GRV (see FIG. 13) may be arranged.

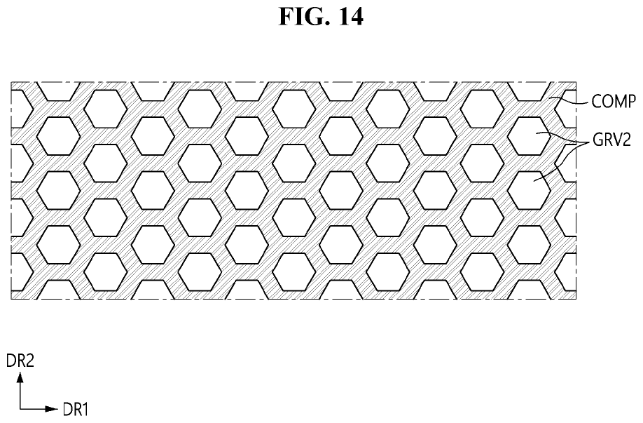

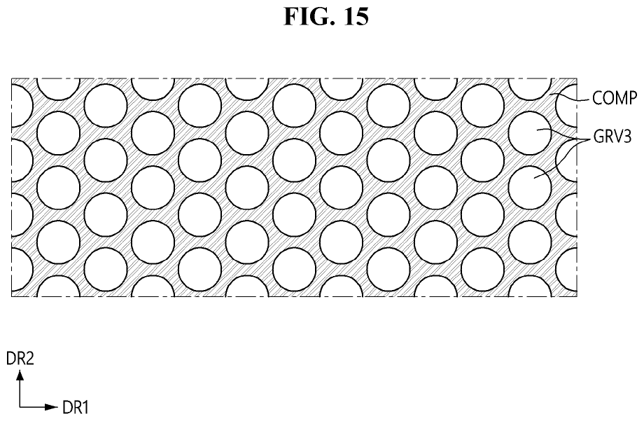

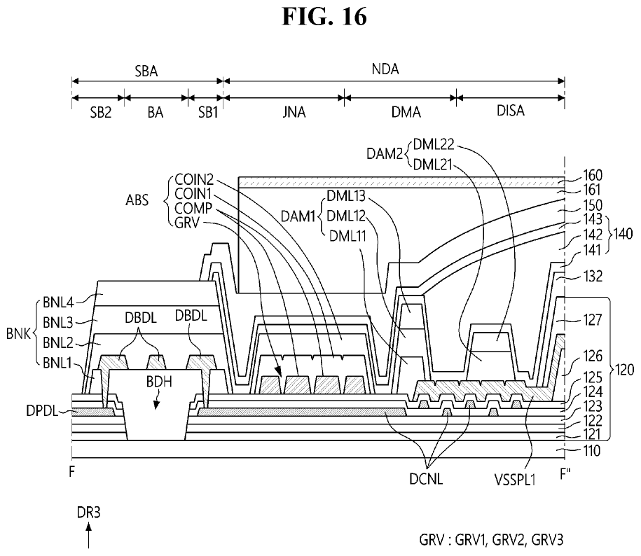

FIG. 13 is a plan view of an example of a compensation pattern layer of a buffer portion according to a third embodiment. FIG. 14 is a plan view of an example of a compensation pattern layer of a buffer portion according to a third embodiment. FIG. 15 is plan view of an example of a compensation pattern layer of a buffer portion according to a third embodiment. FIG. 16 is a schematic cross-sectional view taken along line F-F″ of FIG. 10 according to the third embodiment.

Referring to FIGS. 13 through 16, a display device 10 according to the third embodiment may be substantially the same as the first and second embodiments illustrated in FIGS. 10 through 12 except that the compensation pattern layer COMP of the buffer portion ABS has a mesh shape including grooves having one of a circular shape and a polygonal shape. Thus, any redundant description will be omitted below.

As illustrated in FIGS. 13 through 15, according to the third embodiment, the compensation pattern layer COMP may have a mesh shape including grooves GRV arranged side by side with each other.

The grooves GRV may be alternately arranged at least one by one in the first direction DR1 or the second direction DR2. For example, the grooves GRV may be arranged side by side in the second direction DR2, but grooves GRV in odd-numbered rows may be arranged side by side with each other in the first direction DR1, and grooves GRV in even-numbered rows may be arranged side by side with each other in the first direction DR1.

As illustrated in FIG. 13, each groove GRV1 may have a quadrilateral planar shape.

As illustrated in FIG. 14, each groove GRV2 may have a hexagonal planar shape.

As illustrated in FIG. 15, each groove GRV3 may have a circular planar shape.

However, FIGS. 13 through 15 may be only examples, and the planar shape and size of each groove GRV and the arrangement form of the grooves GRV can be changed without being limited to those illustrated in FIGS. 13 through 15. The grooves GRV may also have a different planar shape and size in each area. Furthermore, the grooves GRV may also be arranged in a different shape in each area.

As illustrated in FIG. 16, the grooves GRV penetrate a third conductive layer. Therefore, a first compensation insulating layer COIN1 covering the compensation pattern layer COMP may contact an interlayer insulating layer 125 through each of the grooves GRV.

As described above, according to the third embodiment, the compensation pattern layer COMP of the buffer portion ABS may be formed in a mesh shape. Therefore, distortion by the compensation pattern layer COPM of signals of at least one line which may overlap the compensation pattern layer COMP can be reduced.

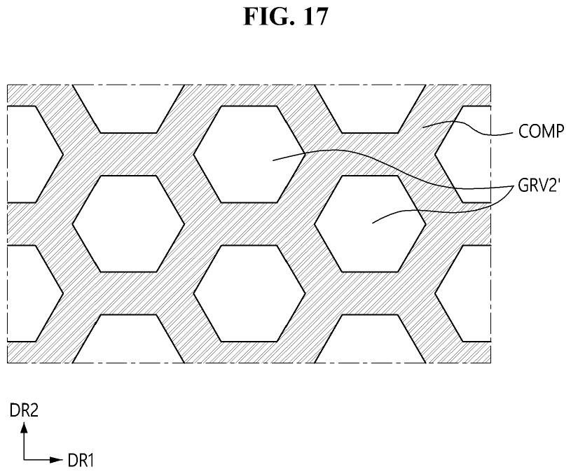

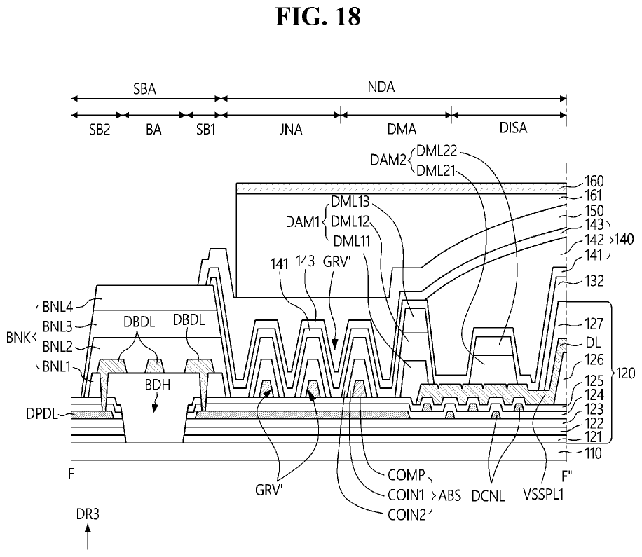

FIG. 17 is a plan view of a compensation pattern layer COMP of a buffer portion ABS according to a fourth embodiment. FIG. 18 is a schematic cross-sectional view taken along line F-F″ of FIG. 10 according to the fourth embodiment.

Referring to FIGS. 17 and 18, a display device 10 according to the fourth embodiment may be substantially the same as the third embodiment illustrated in FIGS. 13 through 16 except that the compensation pattern layer COMP of the buffer portion ABS has a relatively large width. Thus, any redundant description will be omitted below.

According to the fourth embodiment, a width of each groove GRV′ of the compensation pattern layer COMP may be twice or more times thicknesses of one or more compensation insulating layers COIN1 and COIN2 covering side surfaces of the compensation pattern layer COMP.

Accordingly, the grooves GRV′ may not be entirely filled by the compensating insulating layers COIN1 and COIN2. Thus, in a bonding area JNA, a first sealing layer 141 on the buffer portion ABS may contact an interlayer insulating layer 125 through at least at least one of the grooves GRV′ of the compensation pattern layer COMP.

Damage to conductive layers or inorganic insulating materials in the bonding area JNA by the high pressure of a roller in a laminating process can be prevented by the buffer portion ABS. At the same time, the relatively wide grooves GRV′ may increase an area where the inorganic materials may be bonded together in the bonding area JNA, thus making sealing by the sealing layer 140 more firm.

The compensation pattern layer COMP of the buffer portion ABS may be disposed in the shape of a floating island.

The compensation pattern layer COMP of the buffer portion ABS may be maintained at a DC voltage level for electrical stability.

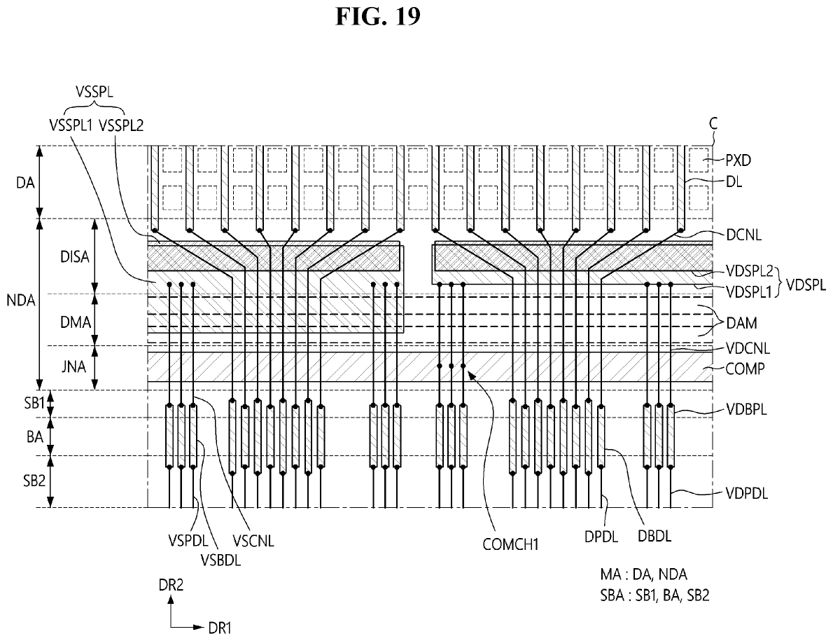

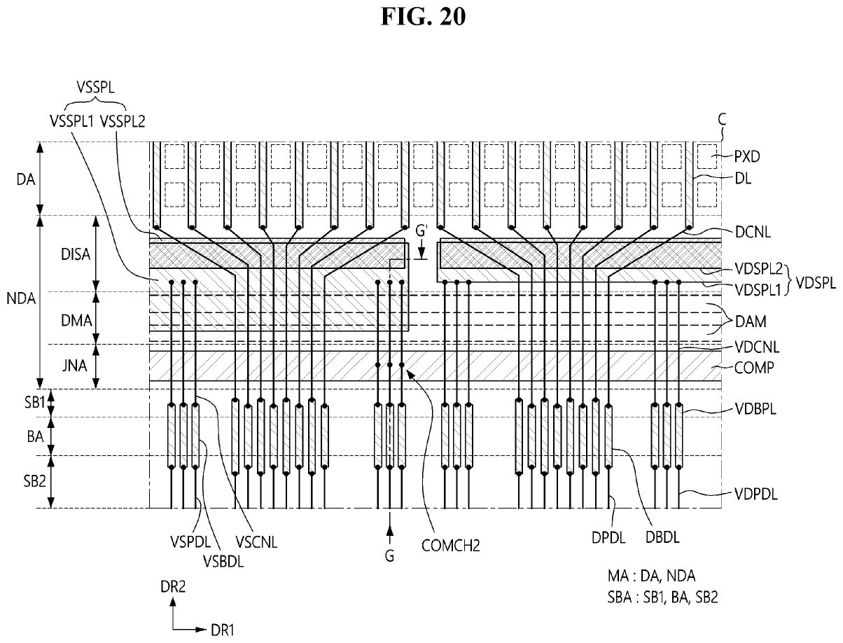

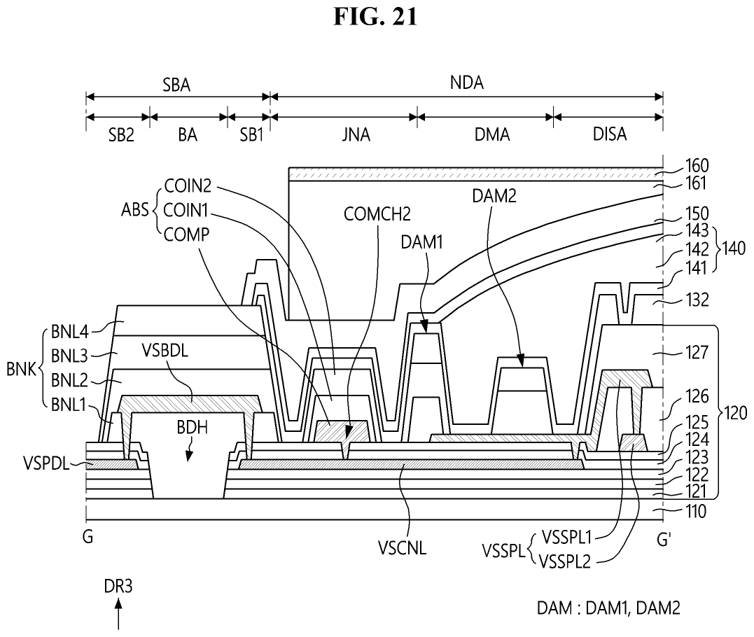

FIGS. 19 and 20 are plan views of portion C of FIG. 4 according to a fifth embodiment. FIG. 21 is a schematic cross-sectional view taken along line G-G′ of FIG. 20.

Referring to FIGS. 19 through 21, a display device 10 according to the fifth embodiment may be substantially the same as the first through fourth embodiments illustrated in FIGS. 10 through 18 except that a compensation pattern layer COMP of a buffer portion ABS may be electrically connected to one of a first power supply line VDSPL and a second power supply line VSSPL. Thus, any redundant description will be omitted below.

As illustrated in FIG. 19, the compensation pattern layer COMP of the buffer portion ABS may be electrically connected to the first power supply line VDSPL.

For example, first power connection lines VDCNL electrically connected to the first power supply line VDSPL may extend from a first sub-area SB1 to a dam separation area DISA via a bonding area JNA and a dam area DMA. Therefore, a portion of the compensation pattern layer COMP may overlap the first power connection lines VDCNL. Accordingly, the compensation pattern layer COMP may be electrically connected to the first power connection lines VDCNL through first compensation connection apertures COMCH1 and thus may be electrically connected to the first power supply line VDSPL.

As illustrated in FIGS. 20 and 21, the compensation pattern layer COMP of the buffer portion ABS may be electrically connected to the second power supply line VSSPL.

For example, second power connection lines VSCNL electrically connected to the second power supply line VSSPL may extend from the first sub-area SB1 to the dam separation area DISA via the bonding area JNA and the dam area DMA. Therefore, a portion of the compensation pattern layer COMP may overlap the second power connection lines VSCNL. Accordingly, the compensation pattern layer COMP may be electrically connected to the second power connection lines VSCNL through second compensation connection apertures COMCH2 and thus may be electrically connected to the second power supply line VSSPL.

As illustrated in FIG. 21, in case that the second power connection lines VSCNL may be included in a first conductive layer on a first gate insulating layer 123, the second compensation connection apertures COMCH2 may penetrate an interlayer insulating layer 125 and a second gate insulating layer 124.

In case that the second power connection lines VSCNL may be included in a second conductive layer on the second gate insulating layer 124, the second compensation connection apertures COMCH2 may penetrate the interlayer insulating layer 125.

The first compensation connection apertures COMCH1 of FIG. 19 may be substantially the same as the second compensation connection apertures COMCH2 except that the first compensation connection apertures COMCH1 overlap the first power connection lines VDCNL instead of the second power connection lines VSCNL, and thus a redundant description thereof will be omitted.

As described above, according to the fifth embodiment, the electric potential of the compensation pattern layer COMP of the buffer portion ABS may be maintained at one of first power ELVDD and second power ELVSS. Therefore, signal distortion of lines due to the compensation pattern layer COMP can be further reduced.

The resistance of a power supply line electrically connected to the compensation pattern layer COMP among the first power supply line VDSPL and the second power supply line VDSPL can be reduced.

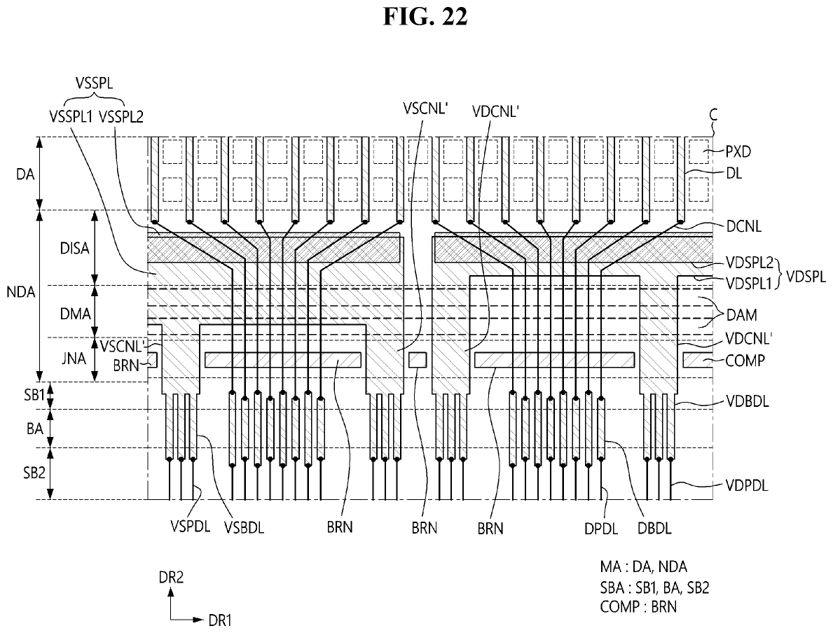

FIG. 22 is a plan view of portion C of FIG. 4 according to a sixth embodiment.

Referring to FIG. 22, a display device 10 according to the sixth embodiment may be substantially the same as the first through fifth embodiments illustrated in FIGS. 10 through 21 except that a compensation pattern layer COMP of a buffer portion ABS may be divided into branches BRN arranged side by side in the first direction DR1. Thus, any redundant description will be omitted below.

According to the sixth embodiment, first power connection lines VDCNL′, second power connection lines VSCNL′, and one of a third conductive layer disposed on an interlayer insulating layer 125 and a fourth conductive layer disposed on a first planarization layer 126 may be a same layer.

In other words, the first power connection lines VDCNL′ may protrude from at least one of a first power main line VDSPL1 and a first power sub-line VDSPL2 and extend toward a sub-area SBA.

The second power connection lines VSCNL′ may protrude from at least one of a second power main line VSSPL1 and a second power sub-line VSSPL2 and extend toward the sub-area SBA.

The compensation pattern layer COMP may be included in the third conductive layer on the interlayer insulating layer 125.

However, in case that each of the first power connection lines VDCNL′, the second power connection lines VSCNL′ and the one of the third conductive layer on the interlayer insulating layer 125 and the fourth conductive layer on the first planarization layer 126 may be a same layer, since organic insulating materials such as the first planarization layer 126 and a second planarization layer 127 may be removed from a part of each of a dam area DMA and a bonding area JNA, a short circuit may occur if the first power connection lines VDCNL′ and the second power connection lines VSCNL′ overlap the compensation pattern layer COMP.

To prevent this, according to the sixth embodiment, the compensation pattern layer COMP may be divided into the branches BRN arranged side by side in the first direction DR1, and the branches BRN may be spaced apart from the first power connection lines VDCNL′ and the second power connection lines VSCNL′.

For electrical stability of the compensation pattern layer COMP, each of the branches BRN may be electrically connected to a first power connection line VDCNL′ or a second power connection line VSCNL′.

Each of the branches BRN may be electrically connected to one of the first power connection line VDCNL′ and the second power connection line VSCNL′.

At least one of the branches BRN may be electrically connected to the first power connection lines VDCNL′, and remaining branches BRN may be electrically connected to the second power connection lines VSCNL′.

As described above according to the sixth embodiment, even if each of the first power connection lines VDCNL′, the second power connection lines VSCNL′, and the one of the third conductive layer disposed on the interlayer insulating layer 125 and the fourth conductive layer disposed on the first planarization layer 126 is a same layer, the compensation pattern layer COMP can be provided in the form of the branches BRN disposed between the first power connection lines VDCNL′ and the second power connection lines VSCNL′.

A display device according to an embodiment includes a substrate, a circuit layer on the substrate, a light emitting element layer on the circuit layer, a sealing layer on the light emitting element layer, and a polarization layer on the sealing layer.

The substrate includes a main area and a sub-area protruding from a side of the main area. The main area includes a display area in which emission areas may be arranged and a non-display area disposed around the display area. The non-display area includes a dam area and a bonding area that surrounds the dam area, the dam area may be spaced apart from the display area and in which one or more dam portions surrounding the display area may be arranged.

The circuit layer includes a buffer portion disposed in a part of the bonding area, which may be adjacent to the sub-area, and spaced apart from each of the sub-area and the dam area. A polarization layer overlaps the light emitting element layer and extends to the non-display area to further overlap the buffer portion.

As described above, since the display device according to the embodiment includes the buffer portion disposed in the bonding area, a roller may be supported by the buffer portion during a laminating process for disposing the polarization layer. Therefore, the pressure of the roller can be prevented from increasing in some parts.

Accordingly, it may be possible to prevent conductive layers or inorganic insulating materials of the circuit layer from being damaged by the process of disposing the polarization layer, thereby improving the quality reliability and lifespan of the display device.

The buffer portion may include a compensation pattern layer, the compensation pattern layer and a fourth conductive layer may be a same layer disposed on an interlayer insulating layer, at least one compensation insulating layer may cover the compensation pattern layer, the at least one compensation insulating layer and one of a first planarization layer and a second planarization layer may be a same layer. Therefore, since no separate deposition process and mask process are added for the placement of the buffer portion, it may be possible to prevent a manufacturing process from becoming complicated due to the placement of the buffer portion.

The compensation pattern layer of the buffer portion may have a mesh shape including grooves.

One of first power and second power may be applied to the compensation pattern layer of the buffer portion.

Accordingly, signal failure of at least one line overlapping the compensation pattern layer can be prevented.

However, the effects of the disclosure may not be restricted to the one set forth herein. The above and other effects of the disclosure will become more apparent to one of daily skill in the art to which the disclosure pertains by referencing the claims.

What is claimed is:

1. A display device comprising:
a substrate comprising a main area and a sub-area protruding from a side of the main area;
a circuit layer disposed on the substrate;
a light emitting element layer disposed on the circuit layer;
a sealing layer disposed on the light emitting element layer; and
a polarization layer disposed on the sealing layer and overlapping the light emitting element layer, wherein
the main area comprises a display area including a plurality of emission areas and a non-display area disposed around the display area,
the non-display area comprises:
a dam area spaced apart from the display area, the dam area including at least one dam portion that surrounds the display area; and
a bonding area surrounding the dam area,
the circuit layer comprises a buffer portion disposed in a part of the bonding area adjacent to the sub-area, the buffer portion being spaced apart from each of the sub-area and the dam area, and
the polarization layer extends to the non-display area and overlaps the buffer portion.

2. The display device of claim 1, wherein the circuit layer comprises:
a semiconductor layer disposed on the substrate;
a first gate insulating layer disposed on the substrate and covering the semiconductor layer;
a first conductive layer disposed on the first gate insulating layer;
a second gate insulating layer disposed on the first gate insulating layer and covering the first conductive layer;
a second conductive layer disposed on the second gate insulating layer;
an interlayer insulating layer disposed on the second conductive layer and covering the second conductive layer;
a third conductive layer disposed on the interlayer insulating layer;
a first planarization layer disposed on the interlayer insulating layer and covering the third conductive layer;
a fourth conductive layer disposed on the first planarization layer; and
a second planarization layer disposed on the first planarization layer and covering the fourth conductive layer, wherein
the at least one dam portion and the buffer portion are disposed on the interlayer insulating layer, and
the sealing layer contacts the interlayer insulating layer in portions of the bonding area external to the buffer portion.

3. The display device of claim 2, wherein
a width of the buffer portion in a first direction is equal to or greater than a width of the sub-area in a first direction,
the first direction intersects a second direction, and
the sub-area protrudes from the main area in the second direction.

4. The display device of claim 3, wherein the buffer portion comprises:
a compensation pattern layer disposed on the interlayer insulating layer;
a first compensation insulating layer covering the compensation pattern layer; and
a second compensation insulating layer disposed on the first compensation insulating layer, wherein
the third conductive layer comprises the compensation pattern layer,
the first compensation insulating layer and the first planarization layer are a same layer, and
the second compensation insulating layer and the second planarization layer are a same layer.

5. The display device of claim 4, wherein
the compensation pattern layer has a mesh shape, the compensation pattern layer comprises a plurality of grooves, and the plurality of grooves are arranged side by side with each other, and
the first compensation insulating layer contacts the interlayer insulating layer through each of the plurality of grooves.

6. The display device of claim 5, wherein each of the plurality of grooves has one of a circular shape and a polygonal shape.

7. The display device of claim 5, wherein the sealing layer comprises:
a first sealing layer disposed in the main area and covering the light emitting element layer and the at least one dam portion;
a second sealing layer disposed on the first sealing layer, overlapping the light emitting element layer, and comprising an organic insulating material; and
a third sealing layer covering the second sealing layer, wherein
the second sealing layer is disposed in a part of the main area, the main area being surrounded by the at least one dam portion,
the first sealing layer contacts the interlayer insulating layer in a part of the bonding area external to the buffer portion, and
the third sealing layer contacts the first sealing layer in the bonding area.

8. The display device of claim 7, wherein the first sealing layer contacts the interlayer insulating layer through at least one of the plurality of grooves in the compensation pattern layer.

9. The display device of claim 4, wherein
the light emitting element layer comprises a plurality of light emitting elements respectively corresponding to the plurality of emission areas,
the circuit layer comprises a first power supply line and a second power supply line disposed in the non-display area and respectively transmitting a first power and a second power to drive the plurality of light emitting elements, and
each of the first power supply line and the second power supply line is spaced apart from the compensation pattern layer of the buffer portion.

10. The display device of claim 9, wherein the compensation pattern layer is electrically connected to one of the first power supply line and the second power supply line.

11. The display device of claim 9, wherein
the first power supply line comprises a first power connection line extending from the non-display area to the sub-area,
the second power supply line comprises a second power connection line extending from the non-display area to the sub-area,
each of the first power connection line, the second power connection line, and one of the third conductive layer and the fourth conductive layer are a same layer,
the compensation pattern layer of the buffer portion is divided into a plurality of branches arranged side by side in the first direction, and
the plurality of branches are spaced apart from each of the first power connection line and the second power connection line in the first direction.

12. The display device of claim 4, further comprising:
a plurality of pixel drivers respectively corresponding to the plurality of emission areas and electrically connected to the plurality of light emitting elements of the light emitting element layer, respectively;
a plurality of data lines transmitting data signals to the plurality of pixel drivers; and
a plurality of data connection lines disposed in the non-display area, electrically connected to the plurality of data lines, respectively, and extending to the sub-area, wherein
the fourth conductive layer comprises the plurality of data lines,
the first conductive layer comprises at least one of the plurality of data connection lines,
the second conductive layer comprises ones of the data connection lines not included in the first conductive layer, and
at least a portion of each of the plurality of data connection lines overlaps the buffer portion.

13. The display device of claim 4, wherein the light emitting element layer comprises:
a plurality of anodes disposed on the second planarization layer of the circuit layer and respectively corresponding to the plurality of emission areas;
a pixel defining layer disposed on the second planarization layer of the circuit layer, the pixel defining layer corresponding to a non-emission area between the emission areas, the pixel defining layer covering edges of each of the plurality of anodes;
a plurality of light emitting layers disposed on the plurality of anodes, respectively; and
a cathode disposed on the pixel defining layer and on the plurality of light emitting layers, the cathode facing the plurality of anodes,
wherein each of the plurality of light emitting elements comprises one of the plurality of light emitting layers disposed between one of the plurality of anodes and the cathode.

14. The display device of claim 13, wherein
the sub-area comprises:
a bending area transformed into a bent shape;
a first sub-area disposed between a first side of the bending area and the main area; and
a second sub-area extending to a second and opposite side of the bending area; and
the circuit layer further comprises:
a plurality of data bending lines disposed in the bending area and electrically connected to the plurality of data connection lines, respectively;
a bending aperture disposed in the bending area and penetrating the first gate insulating layer, the second gate insulating layer and the interlayer insulating layer; and
a bank covering the bending aperture and spaced apart from the buffer portion, wherein
the bank comprises:
a first bank layer covering the bending aperture, the first bank layer and the first planarization layer are a same layer; and
a second bank layer covering the first bank layer, the second bank layer and the second planarization layer are a same layer, and
the fourth conductive layer further comprises the plurality of data bending lines, the plurality of data bending lines are disposed on the first bank layer, and the plurality of data bending lines are covered by the second bank layer.

15. The display device of claim 14, wherein a portion of each of the first bank layer and the second bank layer extends to the non-display area and overlaps the polarization layer.

16. The display device of claim 14, wherein the polarization layer is spaced apart from the bank.

17. A display device comprising:
a substrate comprising a main area and a sub-area protruding from a side of the main area;
a circuit layer disposed on the substrate;
a light emitting element layer disposed on the circuit layer;
a sealing layer disposed on the light emitting element layer;
a touch sensor layer disposed on the sealing layer; and
a polarization layer disposed on the touch sensor layer and overlapping the light emitting element layer, wherein
the main area comprises:
a display area including a plurality of emission areas; and
a non-display area disposed around the display area, the non-display area comprising:
a dam area spaced apart from the display area, the dam area including at least one dam portion surrounding the display area; and
a bonding area surrounding the dam area,
the circuit layer comprises a buffer portion disposed in a part of the bonding area adjacent to the sub-area, the buffer portion being spaced apart from each of the sub-area and the dam area,
the buffer portion comprises a compensation pattern layer and at least one compensation insulating layer covering the compensation pattern layer, and
the polarization layer extends to the non-display area and overlaps the buffer portion.

18. The display device of claim 17, wherein
a width of the compensation pattern layer in a first direction is equal to or greater than a width of the sub-area,
the first direction intersects a second direction, and
the sub-area protrudes from the main area in the second direction.

19. The display device of claim 18, wherein
the light emitting element layer comprises a plurality of light emitting elements respectively corresponding to the plurality of emission areas,
the circuit layer comprises a first power supply line and a second power supply line disposed in the non-display area and respectively transmitting a first power and a second power to drive the plurality of light emitting elements, and
the compensation pattern layer is spaced apart from each of the first power supply line and the second power supply line.

20. The display device of claim 19, wherein the compensation pattern layer is electrically connected to one of the first power supply line and the second power supply line.

21. The display device of claim 19, wherein
the first power supply line comprises a first power connection line extending from the non-display area to the sub-area,
the second power supply line comprises a second power connection line extending from the non-display area to the sub-area,
each of the first power connection line, the second power connection line and one of a first conductive layer and a second conductive layer are a same layer,
the compensation pattern layer of the buffer portion is divided into a plurality of branches arranged side by side in the first direction, and
the plurality of branches are spaced apart from each of the first power connection line and the second power connection line in the first direction.

22. The display device of claim 18, wherein
the compensation pattern layer has a mesh shape,
the compensation pattern layer comprises a plurality of grooves, the plurality of grooves are arranged side by side with each other, and
each of the plurality of grooves has one of a circular shape and a polygonal shape.

23. The display device of claim 22, wherein the circuit layer comprises:
a semiconductor layer disposed on the substrate;
a first gate insulating layer disposed on the substrate and covering the semiconductor layer;
a first conductive layer disposed on the first gate insulating layer;
a second gate insulating layer disposed on the first gate insulating layer and covering the first conductive layer;
a second conductive layer disposed on the second gate insulating layer;
an interlayer insulating layer disposed on the second conductive layer and covering the second conductive layer;
a third conductive layer disposed on the interlayer insulating layer;
a first planarization layer disposed on the interlayer insulating layer and covering the third conductive layer;
a fourth conductive layer disposed on the first planarization layer; and
a second planarization layer disposed on the first planarization layer and covering the fourth conductive layer, wherein
the at least one dam portion and the buffer portion are disposed on the interlayer insulating layer,
the sealing layer contacts the interlayer insulating layer in a portion of the bonding area external to the buffer portion,
the compensation pattern layer of the buffer portion and the third conductive layer are a same layer, and
each of the at least one compensation insulating layer contacts the interlayer insulating layer through each of the plurality of grooves, each of the at least one compensation insulating layer and one of the first planarization layer and the second planarization layer are a same layer.

24. The display device of claim 23, wherein
the sealing layer comprises:
a first sealing layer disposed in the main area and covering the light emitting element layer and the at least one dam portion;
a second sealing layer disposed on the first sealing layer, the second sealing layer overlapping the light emitting element layer, the second sealing layer comprising an organic insulating material; and
a third sealing layer covering the second sealing layer,
the second sealing layer is disposed in a portion of the main area surrounded by the at least one dam portion,
the first sealing layer contacts a portion of the interlayer insulating layer in the portion of the bonding area external to the buffer portion, and
the third sealing layer contacts the first sealing layer in the bonding area.

25. The display device of claim 24, wherein the first sealing layer contacts the interlayer insulating layer through at least one of the plurality of grooves in the compensation pattern layer.
